(19) United States
(12) Patent Application Publication
(10) Pub. No.: US 2025/0308946 A1
(43) Pub. Date: Oct. 2, 2025

(54) SUBSTRATE PROCESSING APPARATUS AND SUBSTRATE PROCESSING METHOD

(71) Applicant: Tokyo Electron Limited, Tokyo (JP)

(72) Inventors: Kanta MORI, Kumamoto (JP); Nobuhiro OGATA, Kumamoto (JP); Hiroshi MARUMOTO, Leuven (BE); Hiroki SAKURAI, Kumamoto (JP); Kenji YADA, Kumamoto (JP)

(21) Appl. No.: 19/082,876

(22) Filed: Mar. 18, 2025

(30) Foreign Application Priority Data
Mar. 28, 2024 (JP) 2024-054949

(51) Int. Cl. H01L 21/67

(52) U.S. Cl. CPC H01L 21/67051; H01L 21/67248

(57) ABSTRACT

A substrate processing apparatus according to the present disclosure includes a substrate holding unit, a nozzle, a fluid supply unit, a processing liquid supply unit, a gas supply unit, and a gas flow rate adjusting unit. The substrate holding unit rotatably holds a substrate. The nozzle is connected to the fluid supply unit, the processing liquid supply unit, and the gas supply unit, and discharges a mixed fluid of a fluid, a processing liquid, and an inert gas onto the substrate. The fluid supply unit supplies the fluid containing pressurized vapor or mist of pure water to the nozzle. The processing liquid supply unit supplies the processing liquid containing at least sulfuric acid to the nozzle. The gas supply unit supplies the inert gas to nozzle. The gas flow rate adjusting unit adjusts a flow rate of the inert gas supplied to the nozzle.

### CROSS-REFERENCE TO RELATED APPLICATIONS

This application is based on and claims priority from Japanese Patent Application No. 2024-054949 filed on Mar. 28, 2024, with the Japan Patent Office, the disclosure of which is incorporated herein in its entirety by reference.

### TECHNICAL FIELD

The present disclosure relates to a substrate processing apparatus and a substrate processing method.

### BACKGROUND

In the related art, sulfuric acid hydrogen peroxide mixture (SPM) treatment has been known as a method of removing a resist film. SPM treatment involves removing a resist film formed on a substrate such as a semiconductor wafer by supplying an SPM solution obtained by mixing sulfuric acid with hydrogen peroxide water, to the substrate.

In addition, as a method for increasing the temperature of the SPM solution, mixing the SPM solution with water vapor has been proposed (e.g., Japanese Patent Laid-open Publication No. 2022-063225).

### SUMMARY

A substrate processing apparatus according to an aspect of the present disclosure includes a substrate holding unit, a nozzle, a fluid supply unit, a processing liquid supply unit, a gas supply unit, and a gas flow rate adjusting unit. The substrate holding unit rotatably holds a substrate. The nozzle discharges a mixed fluid onto the substrate, the mixed fluid being a mixture of a fluid containing vapor or mist of pure water, a processing liquid containing at least sulfuric acid, and an inert gas. The fluid supply unit supplies the fluid containing vapor or mist of pure water to the nozzle. The processing liquid supply unit supplies the processing liquid containing at least sulfuric acid to the nozzle. The gas supply unit supplies the inert gas to the nozzle. The gas flow rate adjusting unit adjusts a flow rate of the inert gas supplied from the gas supply unit to the nozzle.

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE DRAWINGS

FIG. 1 is a schematic plan view of a substrate processing apparatus according to a first embodiment.

FIG. 2 is a schematic side view of the substrate processing apparatus according to the first embodiment.

FIG. 3 is a cross-sectional view of a first nozzle according to the first embodiment taken along a plane orthogonal to the longitudinal direction.

FIG. 4 is a diagram illustrating an example of a cross-sectional shape viewed along line IV-IV illustrated in FIG. 3.

FIG. 5 is a diagram illustrating an example of a cross-sectional shape viewed along line V-V illustrated in FIG. 3.

FIG. 6 is a flowchart illustrating an example of a procedure of processing executed by the substrate processing apparatus according to the first embodiment.

FIG. 7 is a schematic side view of a substrate processing apparatus according to a second embodiment.

FIG. 8 is a cross-sectional view of a first nozzle according to the second embodiment taken along a plane orthogonal to the longitudinal direction.

FIG. 9 is a diagram illustrating an example of a cross-sectional shape viewed along line IX-IX illustrated in FIG. 8.

FIG. 10 is a diagram illustrating an example of a cross-sectional shape viewed along line X-X illustrated in FIG. 8.

FIG. 11 is a schematic cross-sectional view of a first nozzle according to a third embodiment.

FIG. 12 is a cross-sectional view of a first nozzle according to a fourth embodiment taken along a plane orthogonal to the longitudinal direction.

FIG. 13 is a schematic plan view of the first nozzle according to the fourth embodiment as viewed from below.

FIG. 14 is a diagram illustrating an example of a cross-sectional shape viewed along line XIV-XIV illustrated in FIG. 12.

FIG. 15 is a diagram illustrating an example of a cross-sectional shape viewed along line XV-XV illustrated in FIG. 12.

FIG. 16 is a diagram illustrating an example of a cross-sectional shape viewed along line XVI-XVI illustrated in FIG. 12.

FIG. 17 is a schematic side view of a substrate processing apparatus according to a fifth embodiment.

FIG. 18 is a cross-sectional view of a first nozzle according to a sixth embodiment taken along a plane orthogonal to the longitudinal direction.

FIG. 19 is a diagram illustrating an example of a cross-sectional shape viewed along line XIX-XIX illustrated in FIG. 18.

FIG. 20 is a diagram illustrating an example of a cross-sectional shape viewed along line XX-XX illustrated in FIG. 18.

FIG. 21 is a schematic plan view of a first flow path section illustrating in FIG. 18 as viewed from below.

FIG. 22 is an enlarged view of a cross section of a first nozzle according to a seventh embodiment taken along a plane orthogonal to the lateral direction.

FIG. 23 is a cross-sectional view of a first nozzle according to an eighth embodiment taken along a plane orthogonal to the longitudinal direction.

FIG. 24 is a cross-sectional view of a first nozzle according to a ninth embodiment taken along a plane orthogonal to the longitudinal direction.

### DETAILED DESCRIPTION

In the following detailed description, reference is made to the accompanying drawings, which form a part thereof. The illustrative embodiments described in the detailed description, drawings, and claims are not meant to be limiting. Other embodiments may be utilized, and other changes may be made without departing from the spirit or scope of the subject matter presented here.

Hereinafter, modes for carrying out a substrate processing apparatus and a substrate processing method according to the present disclosure (hereinafter referred to as “embodiments”) will be described in detail with reference to the accompanying drawings. The present disclosure is not limited to these embodiments. In addition, the embodiments may be appropriately combined insofar as the processing contents do not contradict each other. In addition, in each of the following embodiments, the same components are denoted by the same reference numerals, and duplicated descriptions will be omitted.

In addition, in the embodiments illustrated below, expressions such as “horizontal” may be used, but these expressions do not necessarily mean “horizontal” in the strict sense. That is, the above expressions shall allow for deviations, for example, in manufacturing accuracy and installation accuracy.

In addition, in order to make the description easier to understand, the drawings referred to below may show an orthogonal coordinate system in which an X-axis direction, a Y-axis direction, and a Z-axis direction orthogonal to each other are defined and the Z-axis direction is a vertically upward direction.

It is known that the temperature of a mixed fluid obtained by mixing an SPM solution with water vapor varies with the discharge flow rate of the water vapor. However, it is difficult to directly measure the discharge flow rate of the water vapor.

Consequently, it is expected to provide a technique that makes it possible to achieve the optimization of substrate processing using a mixed fluid by improving the accuracy and responsiveness of temperature control for the mixed fluid.

In the embodiments illustrated below, a substrate processing apparatus and a substrate processing method that make it possible to improve the accuracy and responsiveness of temperature control for a mixed fluid in SPM treatment will be describe.

The substrate processing apparatus according to the present disclosure may also be applied to solution treatment other than SPM treatment. For example, the substrate processing apparatus according to the present disclosure may be applied to solution treatment using a processing liquid containing at least sulfuric acid.

Examples of “processing liquids containing at least sulfuric acid” other than an SPM solution include processing liquids that react (rise in temperature or increase in etching properties) when mixed with sulfuric acid, for example, dilute sulfuric acid (a mixed solution of sulfuric acid and water), and a mixed solution of sulfuric acid and ozone water. In addition, the “processing liquid containing at least sulfuric acid” may be sulfuric acid.

### Configuration of Substrate Processing Apparatus

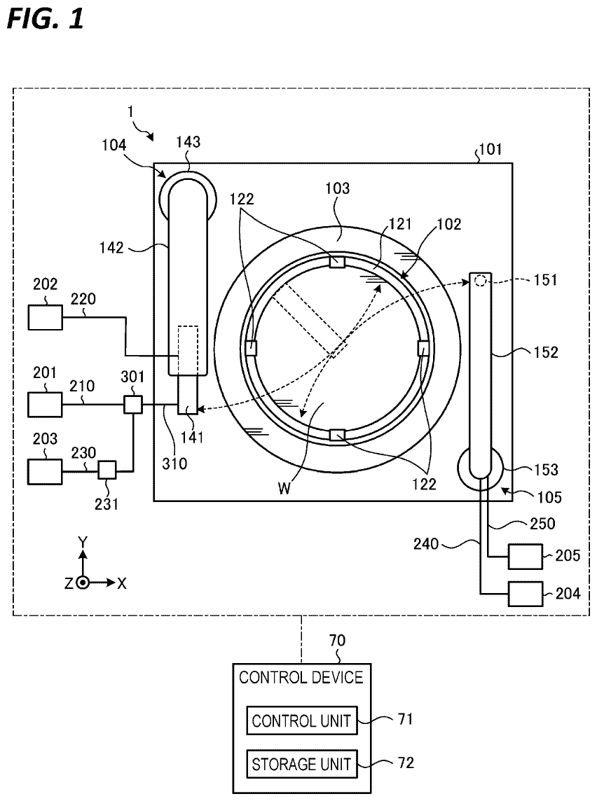

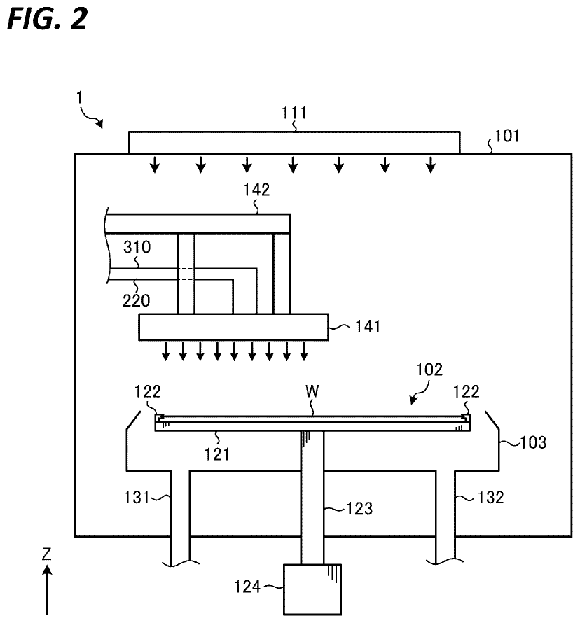

Next, the configuration of a substrate processing apparatus according to the first embodiment will be described with reference to FIGS. 1 and 2. FIG. 1 is a schematic plan view of the substrate processing apparatus according to the first embodiment. In addition, FIG. 2 is a schematic side view of the substrate processing apparatus according to the first embodiment.

As illustrated in FIGS. 1 and 2, a substrate processing apparatus 1 includes a chamber 101, a substrate holding unit 102, a cup 103, a first supply mechanism 104, and a second supply mechanism 105. In addition, the substrate processing apparatus 1 includes a vapor supply unit 201 (an example of a fluid supply), an SPM supply unit 202 (an example of a processing liquid supply), a N₂ gas supply unit 203 (an example of a gas supply), a DIW supply unit 204, and a hydrogen peroxide water supply unit 205. In addition, the substrate processing apparatus 1 includes a N₂ gas flow rate adjusting unit 231 (an example of a gas flow rate adjuster), a first mixing unit 301, and a control device 70.

The chamber 101 houses the substrate holding unit 102, the cup 103, the first supply mechanism 104, and the second supply mechanism 105. The ceiling of the chamber 101 is provided with a fun filter unit (FFU) 111 that forms a downflow in the chamber 101 (see, e.g., FIG. 2).

The substrate holding unit 102 rotatably holds a semiconductor substrate (hereinafter referred to as a “wafer W”) such as, for example, a silicon wafer or a compound semiconductor wafer. For example, the substrate holding unit 102 includes a main body 121 having a larger diameter than the wafer W, a plurality of grippers 122 provided on the upper surface of the main body 121, a support member 123 that supports the main body 121, and a driver 124 that rotates the support member 123. The number of grippers 122 is not limited to that illustrated in the drawings.

Such a substrate holding unit 102 holds the wafer W by gripping the peripheral edge of the wafer W using the plurality of grippers 122. This allows the wafer W to be held horizontally at a slight distance from the upper surface of the main body 121. As described above, a resist film is formed on the surface (upper surface) of the wafer W.

Here, although an example is given of the substrate holding unit 102 that grips the peripheral edge of the wafer W using the plurality of grippers 122, the substrate processing apparatus 1 may be configured to include a vacuum chuck that adsorbs and holds the rear surface of the wafer W instead of the substrate holding unit 102.

The cup 103 is disposed so as to surround the substrate holding unit 102. A liquid exhaust port 131 for exhausting a processing liquid supplied to the wafer W to the outside of the chamber 101 and an air exhaust port 132 for exhausting the atmosphere within the chamber 101 are formed at the bottom of the cup 103.

The first supply mechanism 104 includes a first nozzle 141, a first arm 142 that extends in the horizontal direction and supports the first nozzle 141 from above, and a first revolving and elevating mechanism 143 that revolves and elevates the first arm 142. The first revolving and elevating mechanism 143 enables the first arm 142 to move the first nozzle 141 between a processing position above the wafer W and a standby position outside the wafer W.

The first nozzle 141 is an elongated nozzle that extends linearly in the horizontal direction. The first nozzle 141 has, for example, a length which is approximately the same as the radius of the wafer W. In the state of being located at the processing position, the longitudinal tip of the first nozzle 141 is located above the center of the wafer W, and the longitudinal base end of the first nozzle 141 is located above the peripheral edge of the wafer W.

The first nozzle 141 is connected to the SPM supply unit 202 through an SPM supply path 220. The SPM supply unit 202 supplies an SPM solution which is a mixed solution of sulfuric acid and hydrogen peroxide water to the first nozzle 141 through the SPM supply path 220.

The first nozzle 141 is connected to the vapor supply unit 201 through a first supply path 310, the first mixing unit 301, and a vapor supply path 210. The vapor supply unit 201 generates vapor which is steam of pressurized pure water (deionized water), and supplies the generated vapor to the first mixing unit 301 through the vapor supply path 210.

The first nozzle 141 is connected to the N₂ gas supply unit 203 through the first supply path 310, the first mixing unit 301, a N₂ gas supply path 230, and the N₂ gas flow rate adjusting unit 231. The N₂ gas supply unit 203 supplies N₂ gas which is an inert gas to the first mixing unit 301 through the N₂ gas supply path 230 and the N₂ gas flow rate adjusting unit 231.

The first mixing unit 301 is connected to the vapor supply unit 201 and the N₂ gas supply unit 203, mixes the vapor with the N₂ gas, and supplies a mixed fluid (hereinafter referred to as a “first mixed fluid”) to the first nozzle 141 through the first supply path 310.

The N₂ gas flow rate adjusting unit 231 adjusts the flow rate of the N₂ gas supplied from the N₂ gas supply unit 203 to the first nozzle 141.

The SPM supply unit 202 may be configured using any well-known technique. For example, the SPM supply unit 202 may include a sulfuric acid supply source that supplies sulfuric acid, a hydrogen peroxide water supply source that supplies hydrogen peroxide water, and a mixing unit that mixes sulfuric acid with hydrogen peroxide water. The SPM supply unit 202 may also supply sulfuric acid instead of the SPM solution.

The second supply mechanism 105 includes a second nozzle 151, a second arm 152 that extends in the horizontal direction and supports the second nozzle 151 from above, and a second revolving and elevating mechanism 153 that revolves and elevates the second arm 152. The second revolving and elevating mechanism 153 enables the second arm 152 to move the second nozzle 151 between a processing position above the wafer W and a standby position outside the wafer W.

The second nozzle 151 is connected to the DIW supply unit 204 through a DIW supply path 240. The second nozzle 151 discharges DIW (pure water (deionized water)) supplied from the DIW supply unit 204 through the DIW supply path 240 onto the wafer W. The DIW supply unit 204 supplies the DIW to the second nozzle 151 through the DIW supply path 240. The DIW supply unit 204 may be configured using any publicly-known technique.

In addition, the second nozzle 151 is connected to the hydrogen peroxide water supply unit 205 through a hydrogen peroxide water supply path 250. The second nozzle 151 discharges hydrogen peroxide water supplied from the hydrogen peroxide water supply unit 205 through the hydrogen peroxide water supply path 250 onto the wafer W. The hydrogen peroxide water supply unit 205 supplies hydrogen peroxide water to the second nozzle 151 through the hydrogen peroxide water supply path 250. The hydrogen peroxide water supply path 250 may be configured using any publicly-known technique.

The control device 70 is, for example, a computer, and includes a control unit 71 and a storage unit 72. The storage unit 72 stores programs for controlling various processes executed in the substrate processing apparatus 1. The control unit 71 reads out and executes a program stored in the storage unit 72 to control the operation of the substrate processing apparatus 1. The specific content of control performed by the control unit 71 will be described later.

Such a program may be recorded in a computer-readable storage medium and installed in the storage unit 72 of the control device 70 from the storage medium. Examples of the computer-readable storage medium include a hard disk (HD), a flexible disk (FD), a compact disk (CD), a magneto-optical disk (MO), and a memory card.

### Configuration of Nozzle

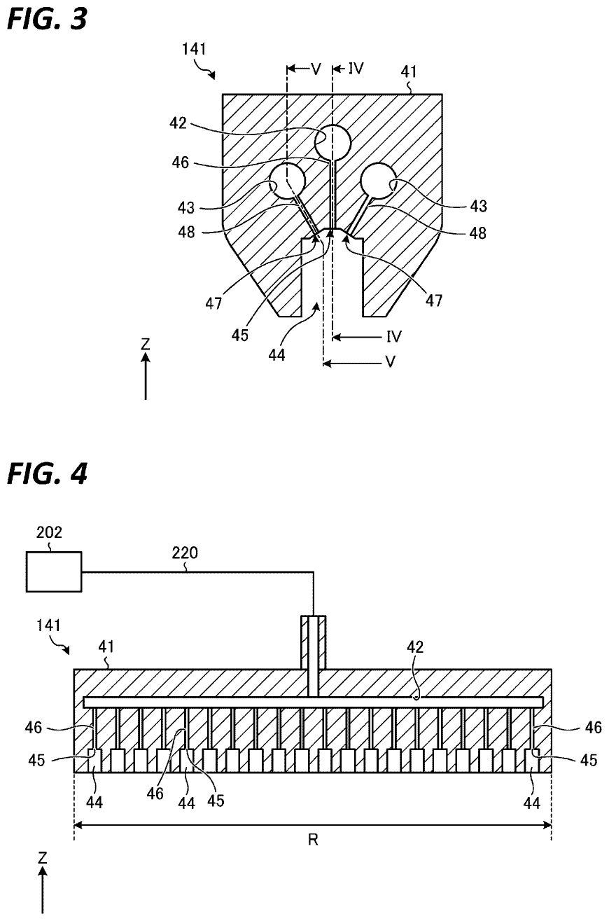

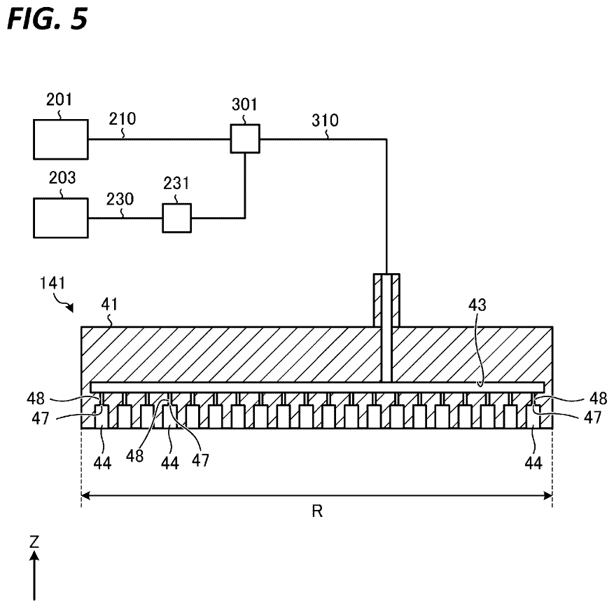

Next, the configuration of the first nozzle 141 will be described with reference to FIGS. 3 to 5. FIG. 3 is a cross-sectional view of the first nozzle 141 according to the first embodiment taken along a plane orthogonal to the longitudinal direction. In addition, FIG. 4 is a diagram illustrating an example of a cross-sectional shape viewed along line IV-IV illustrated in FIG. 3. In addition, FIG. 5 is a diagram illustrating an example of a cross-sectional shape viewed along line V-V illustrated in FIG. 3.

As illustrated in FIG. 3, the first nozzle 141 includes a nozzle body 41, a first distribution path 42 (an example of a processing liquid distribution path), two second distribution paths 43, and a plurality of second mixing units 44. In addition, the first nozzle 141 includes a plurality of first discharge ports 45 and a plurality of first discharge paths 46 (see, e.g., FIG. 4), and a plurality of second discharge ports 47 and a plurality of second discharge paths 48 (see, e.g., FIG. 5).

The first distribution path 42 and the second distribution path 43 are provided inside the nozzle body 41. As illustrated in FIGS. 4 and 5, the first distribution path 42 and the second distribution path 43 extend in the longitudinal direction of the nozzle body 41. The first distribution path 42 is disposed on a median line (a line that bisects the nozzle body 41 into left and right parts) in a cross-sectional view of the nozzle body 41. In addition, the two second distribution paths 43 are disposed on the left and right sides of the first distribution path 42, respectively. Although the two second distribution paths 43 are illustrated in FIG. 3, the number of second distribution paths 43 may be one. In such a case, one second distribution path 43 may be disposed on either the left side or the right side of the first distribution path 42.

The first distribution path 42 is connected to the SPM supply unit 202 through the SPM supply path 220, and distributes the SPM solution supplied from the SPM supply path 220 the entire discharge region R of the first nozzle 141. The second distribution path 43 is connected to the first mixing unit 301 through the first supply path 310, and distributes the first mixed fluid supplied from the first supply path 310 to the entire discharge region R of the first nozzle 141.

The plurality of first discharge ports 45 and the plurality of first discharge paths 46 are provided in the longitudinal direction of the first nozzle 141 (see, e.g., FIG. 4). Each of the first discharge ports 45 is connected to the first distribution path 42 through the first discharge path 46. The plurality of first discharge ports 45 are disposed throughout the entire area of the second mixing unit 44, which will be described later, from one end to the other end in the longitudinal direction.

The plurality of second discharge ports 47 and the plurality of second discharge paths 48 are provided in the longitudinal direction of the first nozzle 141 (see, e.g., FIG. 5). Each of the second discharge ports 47 is connected to the second distribution path 43 through the second discharge path 48. The plurality of second discharge ports 47 are disposed throughout the entire area of the second mixing unit 44, which will be described later, from one end to the other end in the longitudinal direction.

The SPM solution supplied from the SPM supply unit 202 to the first distribution path 42 is distributed from the first distribution path 42 to the plurality of first discharge paths 46, and discharged from each of the first discharge ports 45 to the second mixing unit 44 to be described later. In addition, the first mixed fluid supplied from the first mixing unit 301 to the second distribution path 43 is distributed from the second distribution path 43 to the plurality of second discharge paths 48, and discharged from each of the second discharge ports 47 to the second mixing unit 44 to be described later.

The second mixing unit 44 is provided further downward than the first distribution path 42 and the second distribution path 43. The plurality of first discharge ports 45 and the plurality of second discharge ports 47 open to the upper end surface of the second mixing unit 44. As illustrated in FIGS. 3 to 5, the second mixing unit 44 is a mixing space provided below the nozzle body 41, and mixes the SPM solution with the first mixed fluid. The second mixing unit 44 extends in the vertical direction (here, the Z-axis direction). The lower end of the second mixing unit 44 is open.

The SPM solution discharged from the first discharge port 45 and the first mixed fluid discharged from the second discharge port 47 are mixed near the upper end which is the inlet of the second mixing unit 44. Thus, a mixed fluid of vapor, N₂ gas, and SPM solution (hereinafter referred to as a “second mixed fluid”) is generated inside the second mixing unit 44, and the generated second mixed fluid is discharged from the lower end which is the outlet of the second mixing unit 44 toward the wafer W.

In this way, the substrate processing apparatus 1 according to the first embodiment discharges the second mixed fluid obtained by mixing the SPM solution, vapor, and N₂ gas onto the wafer W. By adding the N₂ gas to the SPM solution and the vapor, an exothermic reaction between the moisture in the vapor and the SPM solution is suppressed. Thus, the temperature of the mixed fluid to which N₂ gas has been added (the second mixed fluid) becomes lower than the temperature of the mixed fluid to which N₂ gas has not been added. The substrate processing apparatus 1 according to the first embodiment may control the discharge temperature of the second mixed fluid discharged from the first nozzle 141 by adjusting the flow rate of the N₂ gas using the N₂ gas flow rate adjusting unit 231. Therefore, according to the substrate processing apparatus 1 of the first embodiment, it is possible to improve the accuracy and responsiveness of temperature control for the mixed fluid.

The control unit 71 (see, e.g., FIG. 1) adjusts the flow rate of the N₂ gas to execute a temperature adjustment process of adjusting the discharge temperature of the second mixed fluid discharged from the first nozzle 141. For example, the control unit 71 controls the N₂ gas flow rate adjusting unit 231 so that the flow rate of the N₂ gas supplied from the N₂ gas supply to the first nozzle 141 becomes a flow rate set in advance.

In the above temperature adjustment process, the flow rate of the vapor supplied from the vapor supply unit 201 to the first nozzle 141 and the flow rate of the SPM solution supplied from the SPM supply unit 202 to the first nozzle 141 are constant.

That is, in the temperature adjustment process, the control unit 71 keeps the flow rates of the vapor and the SPM solution supplied to the first nozzle 141 constant, and adjusts only the flow rate of the N₂ gas supplied to the first nozzle 141. This allows, for example, the output of an instrument that generates vapor to be kept constant, which makes it possible to maintain stable operating conditions. In addition, since the ratio of sulfuric acid and hydrogen peroxide contained in the SPM solution may be kept constant, it is possible to maintain stable operating conditions during the mixing process of the vapor and the SPM solution in which an exothermic reaction occurs.

### Specific Operation of Substrate Processing Apparatus

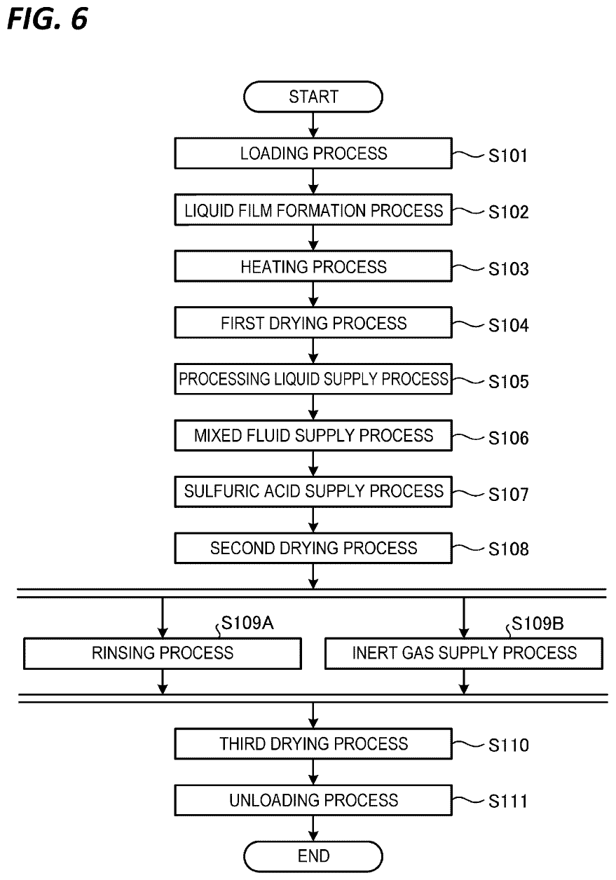

Next, an example of a specific operation of the substrate processing apparatus 1 according to the first embodiment will be described with reference to FIG. 6. FIG. 6 is a flowchart illustrating an example of a procedure of processing executed by the substrate processing apparatus 1 according to the first embodiment. A series of processes illustrated in FIG. 6 is executed under control performed by the control unit 71.

First, a process of loading the wafer W is performed in the substrate processing apparatus 1 (step S101). For example, the wafer W is loaded from a substrate transfer device (not illustrated in FIG. 1) into the chamber 101 of the substrate processing apparatus 1 and held by the substrate holding unit 102. Thereafter, the substrate processing apparatus 1 rotates the substrate holding unit 102 at a predetermined rotational speed.

Next, a liquid film formation process is performed in the substrate processing apparatus 1 (step S102). In the liquid film formation process, first, the second revolving and elevating mechanism 153 (see, e.g., FIG. 1) moves the second nozzle 151 from the standby position to a processing position on the wafer W. Thereafter, DIW is discharge from the second nozzle 151 onto the upper surface of the wafer W. The DIW discharged onto the wafer W is spread over the upper surface of the wafer W by the centrifugal force the rotating wafer W. This allows a liquid film of the DIW to be formed on the upper surface of the wafer W.

Next, a heating process is performed in the substrate processing apparatus 1 (step S103). The heating process is a process of heating the first nozzle 141.

For example, first, the first revolving and elevating mechanism 143 moves the first nozzle 141 from the standby position to a processing position on the wafer W. Thus, the discharge region R of the first nozzle 141 is located above the wafer W. Thereafter, vapor is supplied to the first nozzle 141, and the vapor is discharged from the first nozzle 141 onto the surface of the wafer W. During this time, the DIW continues to be discharged from the second nozzle 151.

In this way, by causing vapor, that is, pressurized DIW steam, to flow into the first nozzle 141, the first nozzle 141 may be heated, and condensation on the first nozzle 141 is suppressed by heating the first nozzle 141. When the SPM solution is supplied into the first nozzle 141 during a processing liquid supply process or a mixed fluid supply process which will be described later, the presence of condensed water inside the first nozzle 141 may cause concern of sudden boiling occurring due to the condensed water reacting with the SPM solution. Meanwhile, sudden boiling may be suppressed by heating the first nozzle 141 to suppress condensation.

In addition, by forming a liquid film on the wafer W in the liquid film formation process prior to the heating process, it is possible to suppress the influence of the vapor discharged from the first nozzle 141 on the wafer W during the heating process.

Next, a first drying process is performed in the substrate processing apparatus 1 (step S104). In the first drying process, the discharge of vapor from the first nozzle 141 and the discharge of DIW from the second nozzle 151 are stopped, and then the wafer W is rotated for a certain period of time to remove moisture remaining on the wafer W.

In this way, by removing moisture from the wafer W, it is possible to prevent the SPM solution discharged onto the wafer W in the processing liquid supply process to be described later from influencing the wafer W due to reaction with the moisture on the wafer W.

Next, the processing liquid supply process is performed in the substrate processing apparatus 1 (step S105). The processing liquid supply process is a process of supplying the SPM solution to the wafer W prior to the mixed fluid supply process to be described later. For example, in the processing liquid supply process, the SPM solution is discharged from the first nozzle 141 onto the upper surface of the wafer W.

In the mixed fluid supply process to be described later, the second mixed fluid is discharged from the first nozzle 141. In this case, if the second mixed fluid is discharged onto the dried wafer W prior to the SPM solution, there may be concern of the discharged second mixed fluid influencing the wafer W. Meanwhile, by performing the processing liquid supply process prior to the mixed fluid supply process, it is possible to suppress the influence of vapor on the wafer W.

In the processing liquid supply process, sulfuric acid or hydrogen peroxide water may also be discharged onto the wafer W instead of the SPM solution. However, in a case where sulfuric acid is discharged first and then hydrogen peroxide water is supplied, the sulfuric acid and hydrogen peroxide water react inside the first nozzle 141 and the pressure increases, which may cause the SPM solution to splash during the subsequent mixed fluid supply process. In addition, in a case where hydrogen peroxide water is discharged first and then sulfuric acid is supplied, the sulfuric acid and hydrogen peroxide water react inside the first nozzle 141, which may generate a large amount of fumes during the subsequent mixed fluid supply process. For this reason, the SPM solution is suitable as a liquid to be supplied to the wafer W prior to the mixed fluid supply process.

The first discharge port 45 from which the SPM solution is discharged has a relatively small diameter. For this reason, in a case where the SPM solution is discharged at a high flow rate in the processing liquid supply process, the flow velocity of the SPM solution become too fast, which may cause the SPM solution to splash on the wafer W. For this reason, the flow rate of the SPM solution in the processing liquid supply process may be set to be lower than the flow rate of the SPM solution in the mixed fluid supply process to be described later.

Next, the mixed fluid supply process is performed in the substrate processing apparatus 1 (step S106). In the mixed fluid supply process, the second mixed fluid is discharged from the first nozzle 141 onto the surface of the wafer W. The vapor and the N₂ gas supplied to the first nozzle 141 are mixed in advance in the first mixing unit 301. A resist film formed on the surface of the wafer W is removed through the mixed fluid supply process. When the mixed fluid supply process is completed, the first revolving and elevating mechanism 143 moves the first nozzle 141 from the processing position to the standby position. The specific content of the mixed fluid supply process will be described later.

The above-described temperature adjustment process, that is, the process of adjusting the flow rate of N₂ gas, need only be executed before the mixed fluid supply process of step S106 is started. In other words, the flow rate of N₂ gas need only be adjusted to a given flow rate by a point in time the mixed fluid supply process is started.

Next, a sulfuric acid supply process is performed in the substrate processing apparatus 1 (step S107). In the sulfuric acid supply process, sulfuric acid is discharged from the first nozzle 141 onto the upper surface of the wafer W. The sulfuric acid is supplied from the SPM supply unit 202. The sulfuric acid discharged onto the wafer W is spread over the upper surface of the wafer W by the centrifugal force of the rotating wafer W.

The SPM solution may remain inside the first nozzle 141 after the mixed fluid supply process. Since the SPM solution has foaming properties, the SPM solution remaining inside the first nozzle 141 causes the SPM solution to foam inside the first nozzle 141, and this foaming causes the SPM solution to run out inside the first nozzle 141, which may lead to the SPM solution falling from the first nozzle 141 onto the wafer W.

Consequently, by replacing the SPM solution remaining inside the first nozzle 141 with sulfuric acid through the sulfuric acid supply process, it is possible to prevent the SPM solution from falling from the first nozzle 141 onto the wafer W.

In the sulfuric acid supply process, hydrogen peroxide water may also be used instead of sulfuric acid. In a case where hydrogen peroxide water is used instead, there may be concern of the hydrogen peroxide water splashing due to reaction with moisture. For this reason, sulfuric acid is suitable as a liquid to replace the SPM solution remaining inside the first nozzle 141.

Next, a second drying process is performed in the substrate processing apparatus 1 (step S108). In the second drying process, the discharge of sulfuric acid from the first nozzle 141 is stopped, and then the wafer W is rotated for a certain period of time to remove sulfuric acid remaining on the wafer W. During the progress of the second drying process, the second revolving and elevating mechanism 153 moves the second nozzle 151 from the standby position to a processing position on the wafer W.

Next, a rinsing process is performed in the substrate processing apparatus 1 (step S109A). In such a rinsing process, hydrogen peroxide water is supplied from the second nozzle 151 to the surface of the wafer W. The hydrogen peroxide water supplied to the wafer W is spread over the surface of the wafer W by the centrifugal force caused by the rotation of the wafer W. This allows the upper surface of the wafer W to be replaced with hydrogen peroxide water.

In this way, in the substrate processing apparatus 1 according to the first embodiment, hydrogen peroxide water is supplied to the wafer W from the second nozzle 151 which is a different nozzle from the first nozzle 141 during the rinsing process. In this way, in a case where the rinsing process is performed using the first nozzle 141, it is possible to suppress liquid splashing due to sudden boiling caused by a reaction between the moisture remaining inside the first nozzle 141 and the hydrogen peroxide water. During the rinsing process, the control unit 71 controls the first revolving and elevating mechanism 143 to move the first nozzle 141 to the standby position. In addition, after the rinsing process is completed, the control unit 71 controls the second revolving and elevating mechanism 153 to move the second nozzle 151 to the standby position.

In addition, in the substrate processing apparatus 1, a N₂ gas supply process is performed in parallel with the rinsing process (step S109B). In such a N₂ gas supply process (an example of an inert gas supply process), N₂ gas is supplied from the first nozzle 141 to the surface of the wafer W. In a case where sulfuric acid and moisture remain inside the first nozzle 141 after the sulfuric acid supply process, there may be concern that the mixed residual liquid, which is a mixture of the remaining sulfuric acid and moisture, will fall onto the wafer W. Since the mixed residual liquid increases in temperature due to the reaction, falling of the mixed residual liquid onto the wafer W causes the wafer W to locally increase in temperature, which may lead to a decrease in the temperature uniformity of the wafer W. Consequently, by exhausting the mixed residual liquid inside the nozzle to the outside of the nozzle through the N₂ gas supply process, it is possible to suppress a decrease in the temperature uniformity of the wafer W caused by falling of the mixed residual liquid. By performing the N₂ gas supply process simultaneously with the rinsing process, it is possible to suppress the influence of the mixed residual liquid and N₂ gas exhausted onto the wafer W from inside the first nozzle 141 on the wafer W.

The start timing of the N₂ gas supply process may be simultaneous with the start timing of the rinsing process, or may be after the start of the rinsing process.

In addition, the N₂ gas supply process does not necessarily have to be performed in parallel with the rinsing process. For example, the N₂ gas supply process may be performed after the second drying process and before the rinsing process, may be performed after the rinsing process and before a third drying process, or may be performed after the third drying process. In this case, the first nozzle 141 may discharge, for example, N₂ gas toward a dummy dispense bath (not illustrated) disposed at a standby position outside the wafer W.

Next, the third drying process is performed in the substrate processing apparatus 1 (step S110). In the third drying process, the control unit 71 increases the rotation speed of the wafer W. This causes a rinse liquid remaining on the wafer W to be shaken off, and the wafer W is dried. Thereafter, the rotation of the wafer W is stopped.

Next, an unloading process is performed in the substrate processing apparatus 1 (step S111). In the unloading process, the wafer W held by the substrate holding unit 102 is transferred to a substrate transfer device (not illustrated in FIG. 1). When such an unloading process is completed, substrate processing for one wafer W is completed.

### Second Embodiment

In the first embodiment, an example in which vapor and N₂ gas are mixed in the first mixing unit 301 provided outside the first nozzle 141 has been described. Without being limited to this, the vapor and the N₂ gas may be mixed inside the first nozzle 141. In the second embodiment, an example in which vapor, N₂ gas, and an SPM solution are mixed inside the first nozzle 141 will be described.

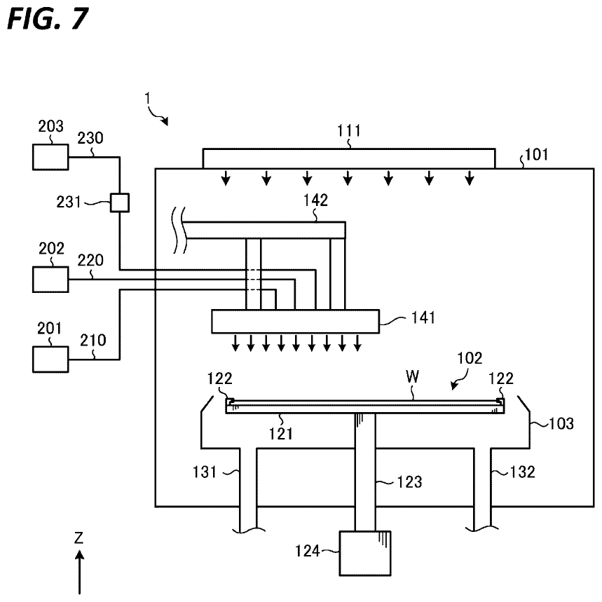

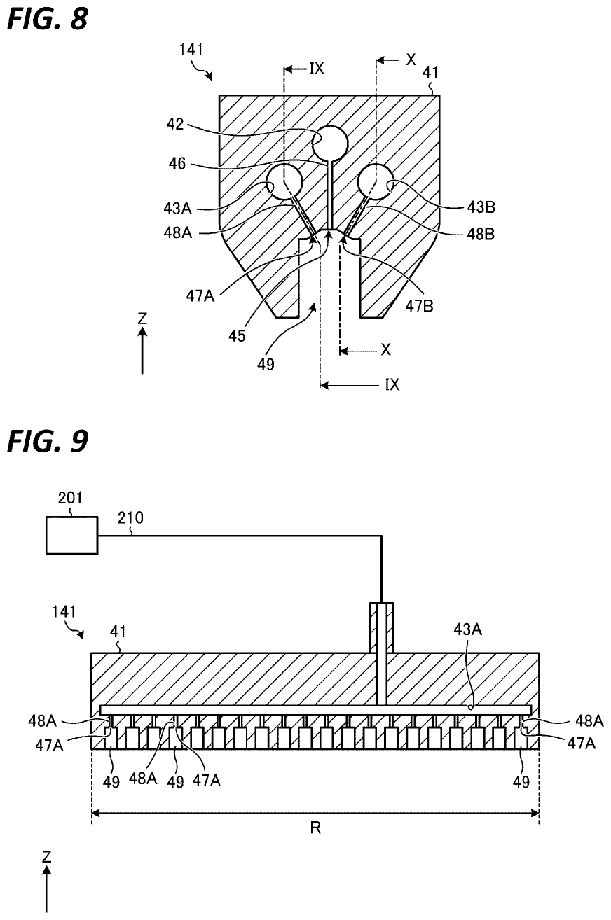

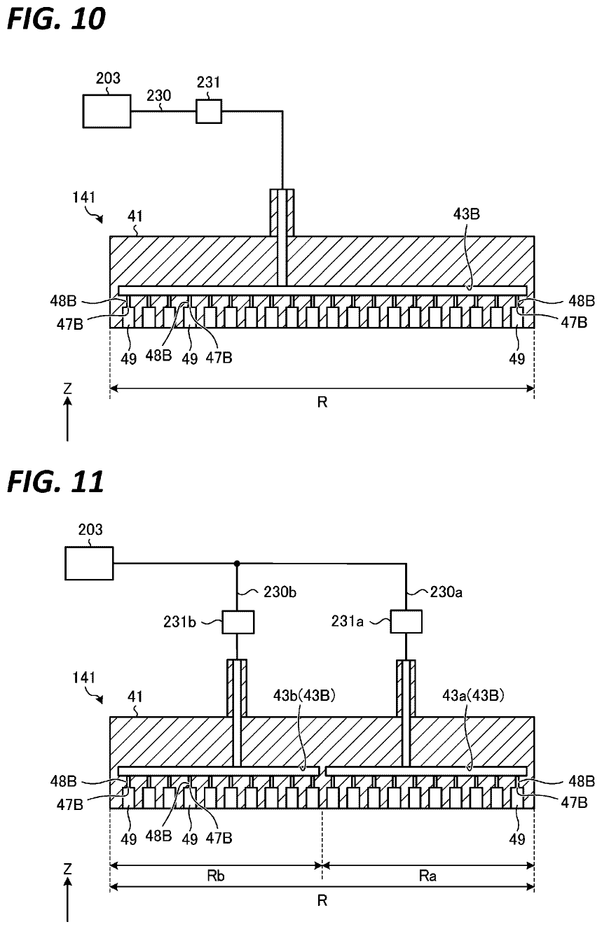

FIG. 7 is a schematic side view of a substrate processing apparatus 1 according to the second embodiment. FIG. 8 is a cross-sectional view of a first nozzle 141 according to the second embodiment taken along a plane orthogonal to the longitudinal direction. In addition, FIG. 9 is a diagram illustrating an example of a cross-sectional shape viewed along line IX-IX illustrated in FIG. 8. In addition, FIG. 10 is a diagram illustrating an example of a cross-sectional shape viewed along line X-X illustrated in FIG. 8.

As illustrated in FIGS. 7 and 8, the substrate processing apparatus 1 may be configured to include a fluid mixing unit 49 that mixes the vapor, the SPM solution, and the N₂ gas inside the first nozzle 141. The fluid mixing unit 49 may have a similar configuration to the second mixing unit 44 according to the above-described first embodiment.

As illustrated in FIG. 8, the first nozzle 141 according to the second embodiment includes a nozzle body 41 (see, e.g., FIGS. 9 and 10), a first distribution path 42 (an example of a processing liquid distribution path), a third distribution path 43A (an example of a fluid distribution path), and a fourth distribution path 43B (an example of a gas distribution path). In addition, the first nozzle 141 includes the plurality of first discharge ports 45 and the plurality of first discharge paths 46 (see, e.g., FIG. 4), a plurality of third discharge ports 47A and a plurality of third discharge paths 48A (see, e.g., FIG. 9), and a plurality of fourth discharge ports 47B and a plurality of fourth discharge paths 48B (see, e.g., FIG. 10). The first distribution path 42, the first discharge port 45, and the first discharge path 46 have been described above, and thus detailed description thereof will be omitted here.

The third distribution path 43A and the fourth distribution path 43B are provided inside the nozzle body 41. As illustrated in FIGS. 9 and 10, the third distribution path 43A and the fourth distribution path 43B extend in the longitudinal direction of the nozzle body 41. In addition, as illustrated in FIG. 8, the third distribution path 43A is disposed on the left side of the first distribution path 42. The fourth distribution path 43B is disposed on the right side of the first distribution path 42. The third distribution path 43A and the fourth distribution path 43B may be configured to be disposed on opposite sides to each other.

The third distribution path 43A is connected to the vapor supply unit 201 through the vapor supply path 210. The third distribution path 43A distributes the vapor supplied from the vapor supply path 210 to the entire discharge region R of the first nozzle 141.

The fourth distribution path 43B is connected to the N₂ gas supply unit 203 through the N₂ gas supply path 230 and the N₂ gas flow rate adjusting unit 231. The fourth distribution path 43B distributes the N₂ gas supplied from the N₂ gas supply path 230 to the entire discharge region R of the first nozzle 141.

The plurality of third discharge ports 47A and the plurality of third discharge paths 48A are provided in the longitudinal direction of the first nozzle 141 (see, e.g., FIG. 9). Each of the third discharge port 47A is connected to the third distribution path 43A through the third discharge path 48A. The plurality of third discharge ports 47A are disposed throughout the entire area of the fluid mixing unit 49, which will be described later, from one end to the other end in the longitudinal direction.

The plurality of fourth discharge ports 47B and the plurality of fourth discharge paths 48B are provided in the longitudinal direction of the first nozzle 141 (see, e.g., FIG. 10). Each of the fourth discharge port 47B is connected to the fourth distribution path 43B through the fourth discharge path 48B. The plurality of fourth discharge ports 47B are disposed throughout the entire area of the fluid mixing unit 49, which will be described later, from one end to the other end in the longitudinal direction.

The vapor supplied from the vapor supply unit 201 to the third distribution path 43A is distributed from the third distribution path 43A to the plurality of third discharge paths 48A, and discharged from each of the third discharge ports 47A to the fluid mixing unit 49 to be described later. The N₂ gas supplied from the N₂ gas supply unit 203 to the fourth distribution path 43B is distributed from the fourth distribution path 43B to the plurality of fourth discharge paths 48B, and discharged from each of the fourth discharge ports 47B to the fluid mixing unit 49 to be described later.

The fluid mixing unit 49 is provided further downward than the third distribution path 43A and the fourth distribution path 43B. The plurality of third discharge ports 47A and the plurality of fourth discharge ports 47B open to the upper end surface of the fluid mixing unit 49. As illustrated in FIGS. 8 to 10, the fluid mixing unit 49 is a mixing space provided below the nozzle body 41, and mixes the vapor, the SPM solution, and the N₂ gas. The fluid mixing unit 49 extends in the vertical direction (here, the Z-axis direction). The lower end of the fluid mixing unit 49 is open.

The SPM solution discharged from the first discharge port 45, the vapor discharged from the third discharge port 47A, and the N₂ gas discharged from the fourth discharge port 47B are mixed near the upper end which is the inlet of the fluid mixing unit 49 to form a second mixed fluid, and discharged from the lower end which is the outlet of the fluid mixing unit 49 toward the wafer W.

In this way, the vapor and the N₂ gas may be mixed inside the first nozzle 141.

### Third Embodiment

In the third embodiment, a description will be given of another example in which vapor, N₂ gas, and an SPM solution are mixed inside the first nozzle 141. For example, in the third embodiment, a description will be given of an example of the first nozzle 141 in which the discharge region R of the first nozzle 141 is divided into a plurality of individual discharge regions, and the flow rate of the N₂ gas is capable of being adjusted for each of these individual discharge regions.

FIG. 11 is a schematic cross-sectional view of a first nozzle 141 according to the third embodiment. The cross-sectional view illustrated in FIG. 11 is equivalent to a cross-sectional view of the first nozzle 141 according to the third embodiment taken along line XX illustrated in FIG. 8.

As illustrated in FIG. 11, the substrate processing apparatus 1 may include a plurality of individual N₂ gas supply paths 230a and 230b and a plurality of individual N₂ gas flow rate adjusting units 231a and 231b.

The plurality of individual N₂ gas supply paths 230a and 230b individually supply N₂ gas supplied from the N₂ gas supply unit 203 to the first nozzle 141.

The plurality of individual N₂ gas flow rate adjusting units 231a and 231b are provided corresponding to the plurality of individual N₂ gas supply paths 230a and 230b, and adjust the flow rate of the N₂ gas supplied from the N₂ gas supply unit 203 to the first nozzle 141. For example, the individual N₂ gas flow rate adjusting unit 231a is provided in the individual N₂ gas supply path 230a, and adjusts the flow rate of N₂ gas flowing through the individual N₂ gas supply path 230a. The individual N₂ gas flow rate adjusting unit 231b is provided in the individual N₂ gas supply path 230b, and adjusts the flow rate of N₂ gas flowing through the individual N₂ gas supply path 230b.

As illustrated in FIG. 11, the fourth distribution path 43B of the first nozzle 141 is divided into a plurality of individual N₂ gas distribution paths 43a and 43b (an example of individual gas distribution paths). The plurality of individual N₂ gas distribution paths 43a and 43b correspond to a plurality of individual discharge regions Ra and Rb. The plurality of individual discharge regions Ra and Rb are regions obtained by dividing the discharge region R of the first nozzle 141 in the horizontal direction, for example, in the longitudinal direction of the first nozzle 141. For example, the individual discharge region Ra corresponds to the central region of the wafer W, and the individual discharge region Rb corresponds to the outer circumferential region of the wafer W. The central region of the wafer W is a region within the in-plane region of the wafer W which includes the center of the wafer W. The outer circumferential region of the wafer W is a region within the in-plane region of the wafer W which is located closer to the outer circumferential side than to the central region and includes at least the outer circumference of the wafer W.

The individual N₂ gas distribution path 43a corresponds to the individual discharge region Ra. The individual N₂ gas distribution path 43a is connected to the individual N₂ gas supply path 230a, and distributes N₂ gas supplied from the N₂ gas supply unit 203 through the individual N₂ gas supply path 230a and the individual N₂ gas flow rate adjusting unit 231a to the entire individual discharge region Ra.

The individual N₂ gas distribution path 43b corresponds to the individual discharge region Rb. The individual N₂ gas distribution path 43b is connected to the individual N₂ gas supply path 230b, and distributes N₂ gas supplied from the N₂ gas supply unit 203 through the individual N₂ gas supply path 230b and the individual N₂ gas flow rate adjusting unit 231b to the entire individual discharge region Rb.

The N₂ gas distributed to the individual N₂ gas distribution paths 43a and 43b is further distributed from the individual N₂ gas distribution paths 43a and 43b to the plurality of fourth discharge paths 48B, and discharged from the plurality of fourth discharge ports 47B to the fluid mixing unit 49.

The SPM solution discharged from the first discharge port 45, the vapor discharged from the third discharge port 47A, and the N₂ gas discharged from the fourth discharge port 47B are mixed near the upper end which is the inlet of the fluid mixing unit 49. This allows a second mixed fluid which is a mixed fluid containing the SPM solution, the vapor, and the N₂ gas to be generated in the fluid mixing unit 49. The generated second mixed fluid is discharged from the lower end which is the outlet of the fluid mixing unit 49 toward the wafer W.

The plurality of individual N₂ gas flow rate adjusting units 231a and 231b adjusts the flow rate of the N₂ gas supplied from the N₂ gas supply unit 203 to the individual N₂ gas distribution paths 43a and 43b under control of the control unit 71. In this way, the substrate processing apparatus 1 according to the third embodiment may adjust the flow rate of N₂ gas for each of the plurality of individual discharge regions Ra and Rb. That is, it is possible to control the temperature of the second mixed fluid discharged onto the surface of the wafer W for each of the plurality of individual discharge regions Ra and Rb. This makes it possible to improve the in-plane temperature uniformity of the wafer W.

For example, the control unit 71 may control the individual N₂ gas flow rate adjusting units 231a and 231b so that the flow rate of N₂ gas supplied to the individual discharge region Rb corresponding to the outer circumferential region of the wafer W is smaller than the flow rate of N₂ gas supplied to the individual discharge region Ra corresponding to the central region of the wafer W. In the mixed fluid supply process in which the second mixed fluid is discharged onto the surface of the wafer W, the discharged second mixed fluid is diffused by centrifugal force because the wafer W is rotating. The temperature of the wafer W is more likely to decrease in the outer circumferential region of the wafer W than in the central region of the wafer W. Consequently, the control unit 71 may control the individual N₂ gas flow rate adjusting units 231a and 231b so that the flow rate of N₂ gas supplied to the individual discharge region Rb is smaller than the flow rate of N₂ gas supplied to the individual discharge region Ra. This makes it possible to increase the temperature of the second mixed fluid discharged to the outer circumferential region of the wafer W, and thus it is possible to effectively improve the in-plane temperature uniformity of the wafer W.

In FIG. 11, the numbers of individual N₂ gas supply paths, individual N₂ gas flow rate adjusting units, and individual N₂ gas distribution paths are not limited to two, and may be three or more.

### Fourth Embodiment

In the fourth embodiment, another example in which vapor, N₂ gas, and an SPM solution are mixed inside the first nozzle 141 will be described. For example, in the fourth embodiment, a description will be given of an example of the first nozzle 141 in which the first mixing unit 301 that mixes vapor with N₂ gas and the second mixing unit 44 that mixes the first mixed fluid mixed in the first mixing unit 301 with the SPM solution are included therein.

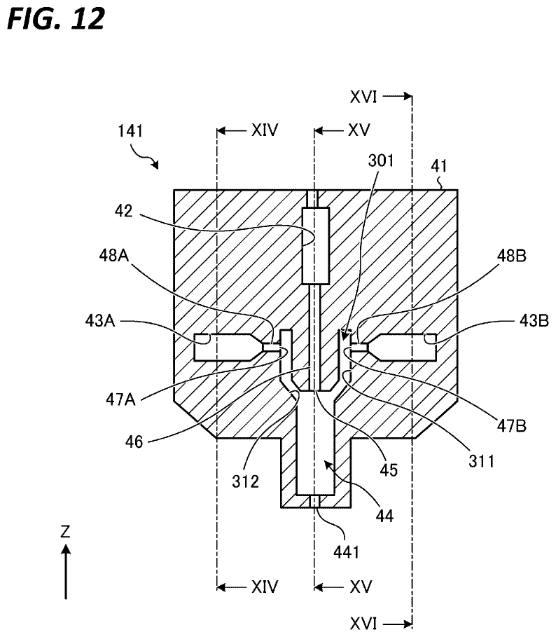

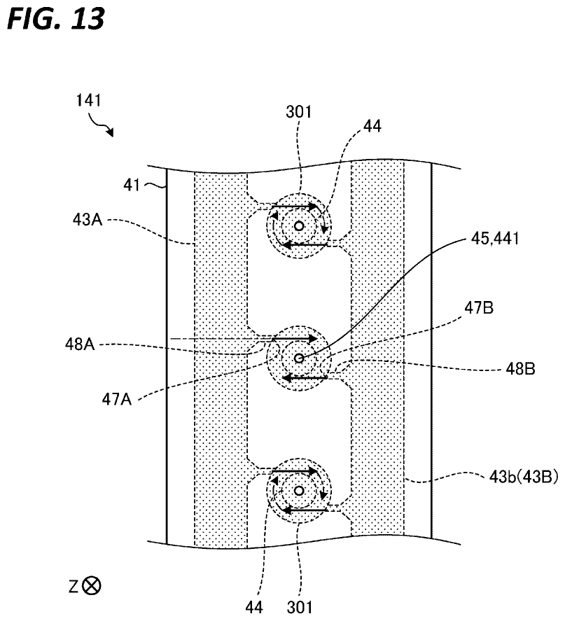

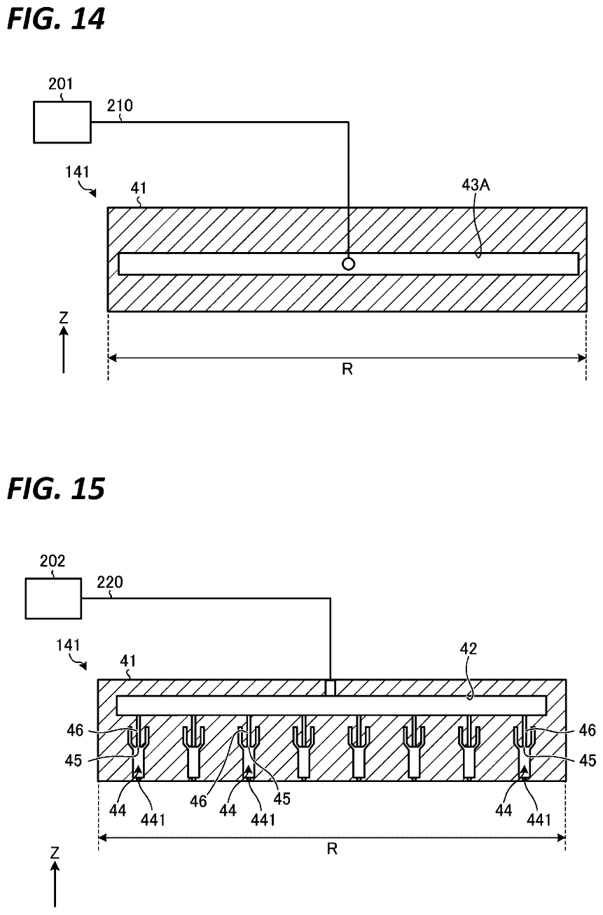

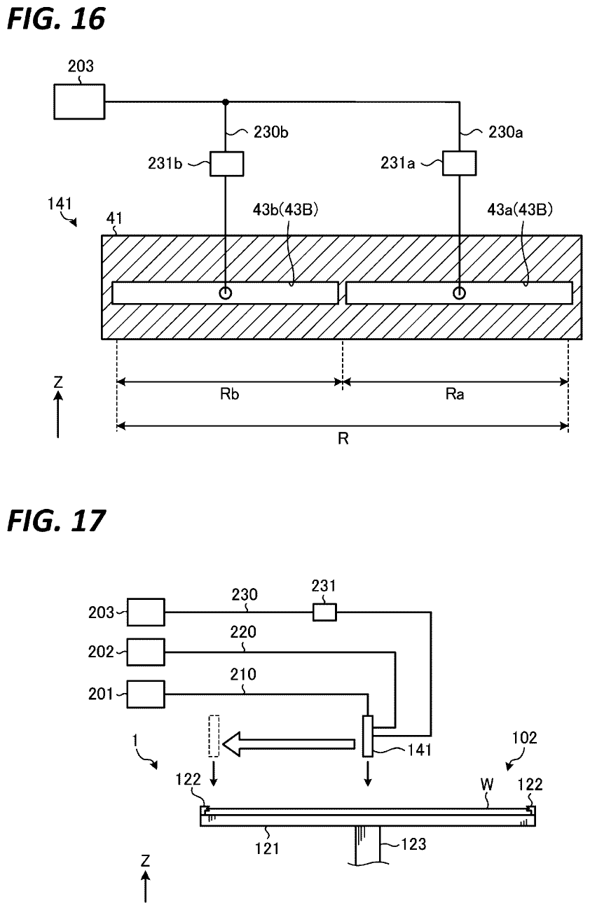

FIG. 12 is a cross-sectional view of a first nozzle 141 according to the fourth embodiment taken along a plane orthogonal to the longitudinal direction. FIG. 13 is a schematic plan view of the first nozzle 141 according to the fourth embodiment as viewed from below. FIG. 14 is a diagram illustrating an example of a cross-sectional shape viewed along line XIV-XIV illustrated in FIG. 12. FIG. 15 is a diagram illustrating an example of a cross-sectional shape viewed along line XV-XV illustrated in FIG. 12. FIG. 16 is a diagram illustrating an example of a cross-sectional shape viewed along line XVI-XVI illustrated in FIG. 12.

As illustrated in FIGS. 14 to 16, the first nozzle 141 is an elongated nozzle. For example, the first nozzle 141 includes the first distribution path 42, the third distribution path 43A, and the fourth distribution path 43B that extend in the longitudinal direction of the first nozzle 141.

As illustrated in FIG. 12, the first nozzle 141 may include the first mixing unit 301 and the second mixing unit 44 therein. As illustrated in FIG. 15, the first mixing unit 301 and the second mixing unit 44 are disposed throughout the entire area of the first nozzle 141 from one end to the other end in the longitudinal direction.

In the fourth embodiment, the first mixing unit 301 may have an annular space formed around the first discharge path 46 so as to surround the first discharge path 46. The third discharge port 47A and the fourth discharge port 47B open to the lateral side of the first mixing unit 301.

The second mixing unit 44 is disposed downstream of the first mixing unit 301. The second mixing unit 44 is disposed coaxially with the first discharge path 46, and communicates with the first discharge path 46 and the first mixing unit 301. The second mixing unit 44 may be linearly formed, the cross-sectional area (diameter) of the second mixing unit 44 may be constant from the inlet to the outlet, and the cross-sectional shape of the first discharge path 46 may be, for example, circular, or elliptical.

The first mixing unit 301 is formed in a cylindrical shape having an annular cross-sectional shape. For example, the first mixing unit 301 has an annular portion 311 and a tapered portion 312 that decreases in diameter as it extends downward. The tapered portion 312 is formed downstream of the annular portion 311, and the outlet of the tapered portion 312 opens in an annular shape between the outlet of the first discharge path 46 and the inlet of the second mixing unit 44.

In the first nozzle 141, the vapor discharged from the third discharge port 47A and the N₂ gas discharged from the fourth discharge port 47B are mixed in the first mixing unit 301. Thereafter, the mixed first mixed fluid and the SPM solution discharged from the first discharge port 45 are mixed in the upper portion of the second mixing unit 44, and the mixed second mixed fluid is discharged from the lower end which is the outlet of the second mixing unit 44 toward the wafer W.

As illustrated in FIG. 13, the first discharge port 45 is disposed coaxially with the first mixing unit 301 and the second mixing unit 44 in a plan view. The first discharge port 45 discharges the SPM solution in a direction along the central axis of the second mixing unit 44 (that is, the Z-axis direction). In addition, the third discharge port 47A is disposed toward a position shifted from the central axis of the first mixing unit 301 in a plan view, and discharges vapor toward the position shifted from the central axis of the first mixing unit 301. Similarly, the fourth discharge port 47B is disposed toward a position shifted from the central axis of the first mixing unit 301 in a plan view, and discharges N₂ gas toward the position shifted from the central axis of the first mixing unit 301. Thus, the vapor and the N₂ gas that collide with the inner surface of the first mixing unit 301 are mixed with the SPM solution discharged from the first discharge port 45 while forming a swirling flow of the first mixed fluid inside the first mixing unit 301 and the second mixing unit 44. In order to form a swirling flow of the vapor, the N₂ gas, and the SPM solution within the second mixing unit 44, the vapor discharged from the third discharge port 47A and the N₂ gas discharged from the fourth discharge port 47B need only flow along the inner surface of the second mixing unit 44.

As illustrated in FIG. 12, an ejection port 441 may be provided at the tip of each of the second mixing units 44. In this case, the ejection port 441 may be formed in an orifice shape having a smaller cross-sectional area than the second mixing unit 44. In a case where there is no orifice-shaped ejection port 441 having a smaller cross-sectional area than the second mixing unit 44 in this way, droplets having grown from fine particles along the inner wall of the second mixing unit 44 are discharged as they are. The cross-sectional area of the ejection port 441 may be constant from the inlet to the outlet, and the cross-sectional shape of the ejection port 441 may be, for example, circular, or elliptical. The droplets that have passed through the second mixing unit 44 are atomized again and injected while passing through the ejection port 441. Therefore, even in a case where the droplets grow large while moving along the inner wall of the second mixing unit 44, the droplets may be atomized to a sufficiently small particle size and injected by passing through the ejection port 441.

In FIG. 12, the first distribution path 42, the third distribution path 43A, and the fourth distribution path 43B have a rectangular cross section, but the cross section may be circular as illustrated in FIG. 8 rather than rectangular.

### Fifth Embodiment

In the first to fourth embodiments described above, examples in which the first nozzle 141 is an elongated nozzle have been described. In the fifth embodiment, an example in which the first nozzle 141 is a nozzle that discharges the second mixed fluid from a single discharge port will be described. FIG. 17 is a schematic side view of a substrate processing apparatus according to the fifth embodiment.

As illustrated in FIG. 17, a substrate processing apparatus 1 according to the fifth embodiment may include, for example, a first nozzle 141 that discharges the second mixed fluid from a single discharge port having a circular shape in a plan view. An example of such a first nozzle 141 capable of being used is an internal mixing-type nozzle that mixes vapor supplied from the vapor supply unit 201, an SPM solution supplied from the SPM supply unit 202, and N₂ gas supplied from the N₂ gas supply unit 203 inside the first nozzle 141.

The first nozzle 141 is capable of horizontal movement between the center and outer circumference of the wafer W by the first revolving and elevating mechanism 143 (an example of a mover) included in the first supply mechanism 104 (see, e.g., FIG. 1).

The vapor supply unit 201 is connected to the first nozzle 141 through the vapor supply path 210. The SPM supply unit 202 is connected to the first nozzle 141 through the SPM supply path 220. In addition, the N₂ gas supply unit 203 is connected to the first nozzle 141 through the N₂ gas supply path 230 and the N₂ gas flow rate adjusting unit 231.

In the mixed fluid supply process, the control unit 71 (see, e.g., FIG. 1) may control the first revolving and elevating mechanism 143 to move the first nozzle 141 in the horizontal direction while discharging the second mixed fluid from the first nozzle 141, thereby allowing the second mixed fluid to be discharged onto the entire surface of the wafer W. In this case, the control unit 71 controls the N₂ gas flow rate adjusting unit 231 in accordance with the horizontal position of the first nozzle 141 so that the flow rate of the N₂ gas supplied to the first nozzle 141 becomes a given flow rate.

For example, for example, the control unit 71 may control the N₂ gas flow rate adjusting unit 231 so that the flow rate of the N₂ gas supplied to the first nozzle 141 at the outer circumference of the wafer W is smaller than the flow rate of the N₂ gas supplied to the first nozzle 141 at the center of the wafer W. In such a case, the temperature of the second mixed fluid to be discharged may be increased at the outer circumference of the wafer W where a drop in temperature is likely to occur, and thus it is possible to effectively improve the in-plane temperature uniformity of the wafer W.

### Sixth Embodiment

In the related art, elongated nozzles that extend linearly in the horizontal direction have been known as nozzles used for substrate processing. However, with conventional elongated nozzles, there has been a problem in that when a mixed fluid is discharged onto a rotating substrate during substrate processing, a temperature difference tends to occur between the center and outer circumference of the substrate. Consequently, it is expected to provide a technique of optimizing substrate processing by using an elongated nozzle capable of adjusting the temperature of a mixed fluid discharged along the longitudinal direction of the nozzle.

In the sixth embodiment, an example of a first nozzle 141 capable of adjusting the temperature of a mixed fluid to be discharged in the longitudinal direction will be described. In addition, in the sixth embodiment, a mixed fluid obtained by mixing vapor with an SPM solution (a third mixed fluid to be described later) will be described as an example of the mixed fluid.

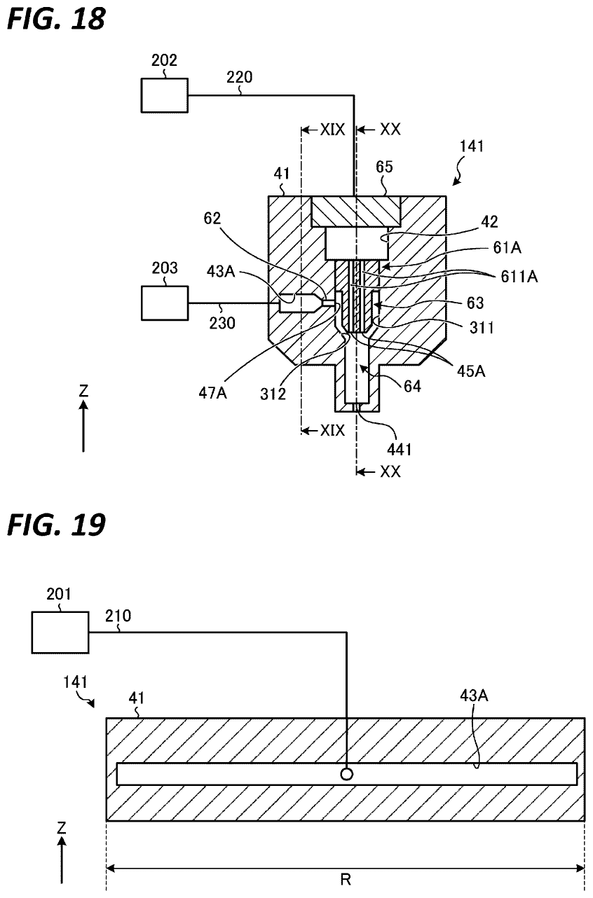

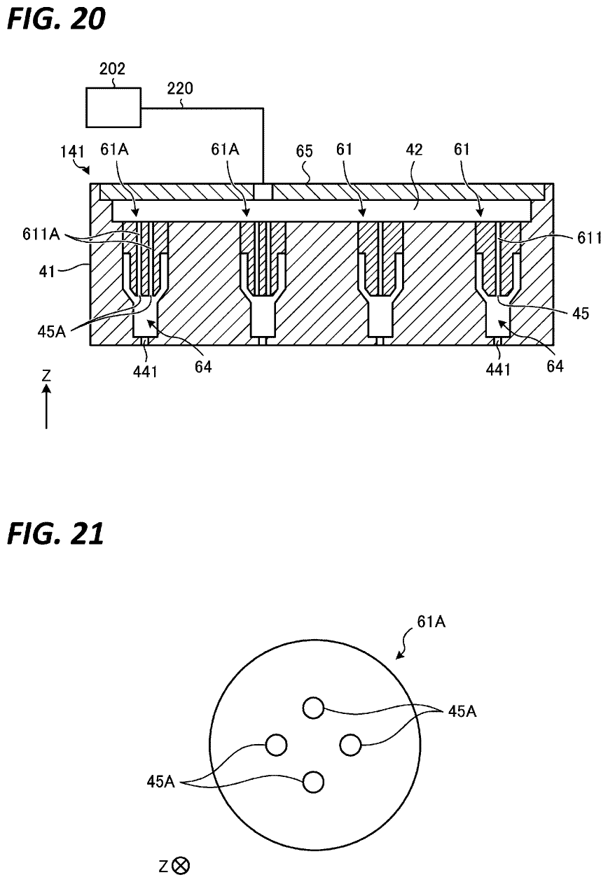

FIG. 18 is a cross-sectional view of a first nozzle 141 according to the sixth embodiment taken along a plane orthogonal to the longitudinal direction. FIG. 19 is a diagram illustrating an example of a cross-sectional shape viewed along line XIX-XIX illustrated in FIG. 18. FIG. 20 is a diagram illustrating an example of a cross-sectional shape viewed along line XX-XX illustrated in FIG. 18.

As illustrated in FIGS. 18 to 20, the first nozzle 141 according to the sixth embodiment is an elongated nozzle that extends linearly in the horizontal direction. The first nozzle 141 includes a plurality of introduction spaces 63 and a plurality of third mixing units 64 therein. In addition, the first nozzle 141 includes a plurality of first flow path sections 61 and 61A, a plurality of second flow path sections 62, and a lid 65.

As illustrated in FIG. 18, in the first nozzle 141 according to the sixth embodiment, the third distribution path 43A is disposed on the side (here, the left side) of the first distribution path 42. The third distribution path 43A need only be disposed on either the left side or the right side of the first distribution path 42. As illustrated in FIG. 19, the third distribution path 43A extends in the longitudinal direction of the nozzle body 41.

The plurality of second flow path sections 62 connect the third distribution path 43A and the introduction space 63. The plurality of second flow path sections 62 are provided in the longitudinal direction of the first nozzle 141. For example, the plurality of second flow path sections 62 are disposed throughout the entire area of the third mixing unit 64, which will be described later, from one end to the other end in the longitudinal direction. The third discharge port 47A is located at the tip of each of the second flow path sections 62, and the third discharge port 47A opens to the lateral side of the introduction space 63 to be described later.

The vapor supplied from the vapor supply unit 201 to the third distribution path 43A is distributed from the third distribution path 43A to the plurality of second flow path sections 62, and is discharged from the third discharge port 47A located at the tip of each of the second flow path sections 62 into the introduction space 63 to be described later.

As illustrated in FIG. 20, the plurality of first flow path sections 61 and 61A are provided in the longitudinal direction of the first nozzle 141. For example, the plurality of first flow path sections 61 and 61A are disposed throughout the entire area of the third mixing unit 64, which will be described later, from one end to the other end in the longitudinal direction.

The first flow path section 61 has one flow path 611 therein. In addition, the first flow path section 61 has one the first discharge port 45 communicating with the flow path 611 at its lower end. The flow path 611 extends linearly in the axial direction of the first flow path section 61. The flow path 611 connects the first distribution path 42 and the third mixing unit 64.

The first flow path section 61A includes a plurality of (here, two) flow paths 611A therein. In addition, the first flow path section 61A has a plurality of (here, two) first discharge ports 45A communicating with each of the flow paths 611A at its lower end. The flow path 611A extends linearly in the axial direction of the first flow path section 61A. The flow path 611A connects the first distribution path 42 and the third mixing unit 64.

The SPM solution supplied from the SPM supply unit 202 to the first distribution path 42 is distributed from the first distribution path 42 to the plurality of first flow path sections 61 and 61A, and is discharged from the plurality of first discharge ports 45 and 45A located at the lower end of each of the first flow path sections 61 and 61A into the introduction space 63 to be described later.

The introduction space 63 is an annular space portion formed around the first flow path section 61 so as to surround the first flow path section 61. The third discharge port 47A opens to the lateral side of the introduction space 63.

The third mixing unit 64 is disposed coaxially with the first flow path section 61 or the first flow path section 61A, and communicates with the first flow path section 61 or the first flow path section 61A and the introduction space 63. The dashed line XX in FIG. 18 (hereinafter referred to as “axis XX”) indicates an axis that passes through the center of the ejection port 441 and extends in the axial direction of the first flow path sections 61 and 61A. The third mixing unit 64 may be linearly formed and that the cross-sectional area (diameter) of the third mixing unit 64 is constant from the inlet to the outlet, and the cross-sectional shape of the first flow path sections 61 and 61A may be, for example, circular or elliptical.

FIG. 21 is a schematic plan view of the first flow path section 61A illustrated in FIG. 18 as viewed from below. As illustrated in FIG. 21, the first flow path section 61A includes a plurality of first discharge ports 45A having a circular shape at the lower end of the first flow path section 61A. The plurality of first discharge ports 45A are provided corresponding to a plurality of flow paths 611A located inside the first flow path section 61A, and discharge the SPM solution supplied through the flow path 611A to the third mixing unit 64. Although four first discharge ports 45A are illustrated in FIG. 21, the number of first discharge ports 45A is not limited to four. The number of first discharge ports 45A may be one, or may be two or more.

An annular portion 311 and a tapered portion 312 that decreases in diameter as it extends downward are formed in the introduction space 63. The tapered portion 312 is formed downstream of the annular portion 311, and the outlet of the tapered portion 312 opens annularly between the outlet of the first flow path section 61 or the first flow path section 61A and the inlet of the third mixing unit 64.

In the first nozzle 141 according to the sixth embodiment, vapor is discharged from the third discharge port 47A into the introduction space 63. The vapor discharged into the introduction space 63 flows downstream while forming a swirling flow in the introduction space 63. Thereafter, the vapor and the SPM solution discharged from the first discharge port 45 or the first discharge port 45A are mixed in the upper portion of the third mixing unit 64, and the mixed fluid of the vapor and the SPM solution thus generated (hereinafter referred to as a “third mixed fluid”) is ejected from the ejection port 441 located at the lower end of each of the third mixing units 64 toward the surface of the wafer W.

As described above, the first flow path sections 61 and 61A and the third mixing unit 64 are disposed coaxially. For example, the centers of the first flow path sections 61 and 61A and the center of the third mixing unit 64 are disposed on the axis XX passing through the center of the ejection port 441. The first discharge port 45 located at the lower end of the first flow path section 61 is also disposed on the axis XX. Meanwhile, the plurality of first discharge ports 45A located at the lower end of the first flow path section 61A are disposed at positions shifted from the axis XX passing through the center of the ejection port 441.

In a case where the center of the first discharge port 45A is disposed coaxially with the center of the ejection port 441, there is concern that the SPM solution discharged from the first discharge port 45A will be ejected from the ejection port 441 without being sufficiently mixed with the vapor. Meanwhile, by shifting the center of the first discharge port 45A from the center of the ejection port 441, the SPM solution and the vapor tends to be mixed inside the third mixing unit 64. Therefore, it is possible to improve the responsiveness of adjustment of the temperature of the third mixed fluid to be discharged.

The lid 65 is provided above the nozzle body 41. As illustrated in FIG. 20, the lid 65 extends in the longitudinal direction of the nozzle body 41.

The lid 65 is configured to be detachable from the nozzle body 41. In such a case, by detaching the lid 65 from the nozzle body 41, it is possible to access the inside of the nozzle body 41, and to replace the first flow path sections 61 and 61A located inside the nozzle body 41 from the upper portion of the nozzle body 41.

In this way, the plurality of first flow path sections 61 and 61A may be detachable from each of the introduction spaces 63. This makes it possible to adjust the discharge temperature of the third mixed fluid in the horizontal direction of the first nozzle 141 (the longitudinal direction of the first nozzle 141) by changing only the shape of the first flow path sections 61 and 61A. Therefore, it is possible to reduce the cost of equipment required for improving the in-plane temperature uniformity of the wafer W.

The lid 65 may be fixed to the nozzle body 41 by a fixing mechanism (not illustrated). The fixing mechanism (not illustrated) may be, for example, a mechanism for fixing the nozzle body 41 and the lid 65 with bolts. The lid 65 may fix the plurality of first flow path sections 61 and 61A by pressing the plurality of first flow path sections 61 from above in a state where the lid is attached to the nozzle body 41.

As described above, the first nozzle 141 according to the sixth embodiment includes at least one or more first flow path sections 61A that differ from the others in the number of flow paths located therein. In the example illustrated in FIG. 20, the first nozzle 141 includes two first flow path sections 61 each having one flow path 611 therein, and two first flow path sections 61A each having two flow paths 611A therein. In other words, the first nozzle 141 includes two types of first flow path sections 61 and 61A that differ in the number of flow paths.

According to the first nozzle 141 having such a configuration, the flow rate of the SPM solution supplied to the third mixing unit 64 may be adjusted depending on the number of flow paths included in the first flow path sections 61 and 61A, and thus it is possible to adjust the temperature of the third mixed fluid ejected from the ejection port 441 to each of the third mixing units 64. Therefore, it is possible to improve the in-plane temperature uniformity of the wafer W.

For example, as illustrated in FIG. 20, the first nozzle 141 may be configured such that the plurality of first flow path sections 61A are disposed in the outer circumferential region of the first nozzle 141 corresponding to the outer circumference of the wafer W, and that the plurality of first flow path sections 61 are disposed in a central region corresponding to the center of the wafer W. In this configuration, the flow rate of the third mixed fluid discharged from the ejection port 441 to the outer circumference of the wafer W is greater than the flow rate of the mixed fluid discharged from the ejection port 441 to the center of the wafer W. As a result, it is possible to increase the temperature of the third mixed fluid discharged from the ejection port 441 at the outer circumference of the wafer W where a drop in temperature is likely to occur. Therefore, it is possible to effectively improve the in-plane temperature uniformity of the wafer W.

### Seventh Embodiment

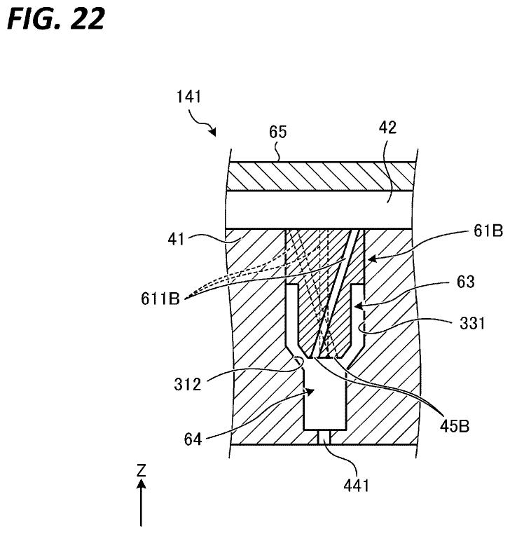

In the above-described sixth embodiment, an example in which the plurality of flow paths 611A extends parallel to the axis of the first flow path section 61A, for example, extends in the vertical direction has been described. In the seventh embodiment, an example of a first nozzle 141 including a first flow path section in which a plurality of flow paths extend in a direction inclined with respect to the vertical direction, instead of such a first flow path section 61A, will be described. FIG. 22 is an enlarged view of a cross section of a first nozzle according to the seventh embodiment taken along a plane orthogonal to the lateral direction.

As illustrated in FIG. 22, the first nozzle 141 may include first flow path sections 61B instead of the first flow path section 61A according to the sixth embodiment. The first flow path section 61B has a plurality of flow paths 611B therein that extend linearly in a direction inclined with respect to the axial direction (vertical direction). In addition, the first flow path section 61B has a plurality of first discharge ports 45B communicating with the plurality of flow paths 611B, respectively. The plurality of first discharge ports 45B are disposed at positions shifted from the axis passing through the center of the ejection port 441, similar to the first discharge port 45A described above.

In the seventh embodiment, the SPM solution is discharged from the first discharge port 45B obliquely with respect to the third mixing unit 64. This makes it possible to lengthen the residence time of the SPM solution in the third mixing unit 64 compared with a case where the SPM solution is discharged in the vertical direction. Therefore, according to the first nozzle 141 of the seventh embodiment, it is possible to effectively improve the mixability of the SPM solution with the vapor forming a swirling flow inside the third mixing unit 64.

The first nozzle 141 according to the seventh embodiment may include a plurality of first flow path sections 61 and a plurality of first flow path sections 61B. In this case, the first nozzle 141 may be configured such that the plurality of first flow path sections 61B are disposed in the outer circumferential region of the first nozzle 141 corresponding to the outer circumference of the wafer W, and that the plurality of first flow path sections 61 are disposed in a central region corresponding to the center of the wafer W. The first flow path section 61B has higher mixability of the SPM solution with the vapor than the first flow path section 61. For this reason, the temperature of the third mixed fluid discharged from the ejection port 441 through the first flow path section 61B is higher than the temperature of the third mixed fluid discharged from the ejection port 441 through the first flow path section 61. Therefore, with such a configuration, it is possible to make the temperature of the third mixed fluid discharged to the outer circumference of the wafer W higher than the temperature of the mixed fluid discharged to the center of the wafer W. This allows the temperature of the third mixed fluid to be prevented from decreasing at the outer circumference of the wafer W, and thus it is possible to improve the in-plane temperature uniformity of the wafer W.

The number of flow paths 611B in the first flow path section 61B does not necessarily have to be plural. That is, the first flow path section 61B may be configured to include one flow path 611B extending obliquely.

The first discharge port 45B may be located on the lateral side of the first flow path section 61B rather than the lower end of the first flow path section 61B. In this case, the SPM solution is discharged from the first discharge port 45B to the introduction space 63, and thus it is possible to further improve the mixability with the vapor.

### Eighth Embodiment

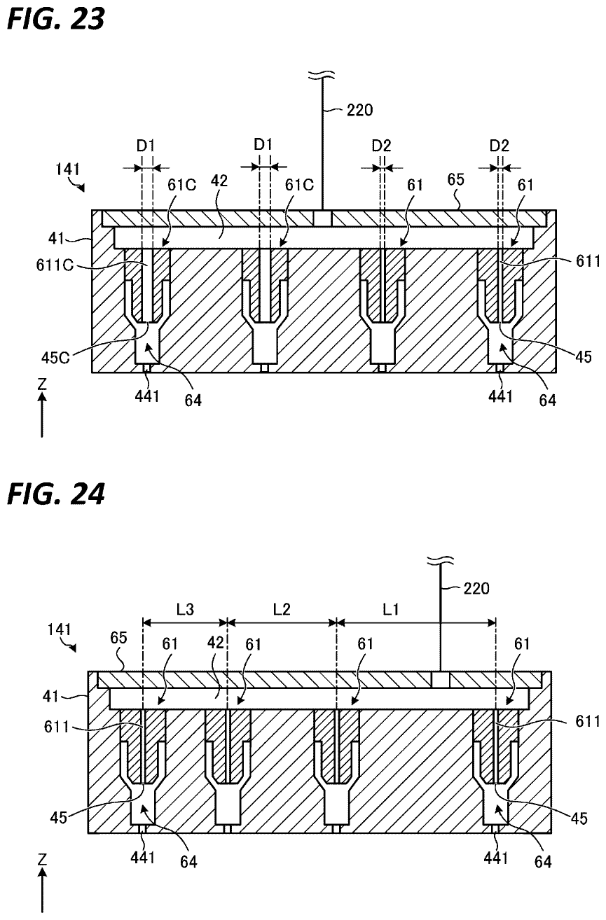

In the eighth embodiment, an example in which a first nozzle 141 has a plurality of types of first flow path sections with different flow path diameters will be described. FIG. 23 is a cross-sectional view of a first nozzle 141 according to the eighth embodiment taken along a plane orthogonal to the longitudinal direction.

As illustrated in FIG. 23, the first nozzle 141 according to the eighth embodiment may include two types of first flow path sections, that is, a first flow path section 61 and a first flow path section 61C.

The first flow path section 61 includes one flow path 611, and the first flow path section 61C also includes one flow path 611C. Both of the flow paths 611 and 611C extend in the axis of first flow path sections 61 and 61C, in other words, extend in the vertical direction.

A flow path diameter D1 of the flow path 611C of the first flow path section 61C is larger than a flow path diameter D2 of the flow path 611 of the first flow path section 61.

In this way, the first nozzle 141 may be configured to include the first flow path section 61C having the flow path 611C with the flow path diameter D1 larger than the flow path diameter D2 of the flow path 611 included in the other first flow path section 61. According to the first nozzle 141 having such a configuration, it is possible to adjust the flow rate of the SPM solution supplied to the third mixing unit 64 using the flow path diameters of the flow paths 611 and 611C included in the first flow path sections 61 and 61C. That is, according to the first nozzle 141 of the eighth embodiment, it is possible to adjust the temperature of the third mixed fluid ejected from the ejection port 441 using the flow path diameters of the flow paths 611 and 611C included in the first flow path sections 61 and 61C. Therefore, it is possible to improve the in-plane temperature uniformity of the wafer W.

For example, as illustrated in FIG. 23, the first nozzle 141 may be configured such that a plurality of first flow path sections 61C are disposed in the outer circumferential region of the first nozzle 141 corresponding to the outer circumference of the wafer W, and that a plurality of first flow path sections 61 are disposed in a central region corresponding to the center of the wafer W. With such a configuration, it is possible to increase the temperature of the third mixed fluid discharged from the ejection port 441 at the outer circumference of the wafer W where a drop in temperature is likely to occur. Therefore, it is possible to effectively improve the in-plane temperature uniformity of the wafer W.

### Ninth Embodiment

In the sixth to eighth embodiments described above, a case in which the plurality of ejection ports 441 are disposed at equal intervals throughout the entire area of the first nozzle 141 in the longitudinal direction has been described. In other words, a case in which the plurality of first flow path sections are disposed at equal intervals throughout the entire area of the first nozzle 141 in the longitudinal direction has been described. In the ninth embodiment, an example in which a plurality of first flow path sections are disposed at different intervals will be described. FIG. 24 is a cross-sectional view of a first nozzle 141 according to the ninth embodiment taken along a plane orthogonal to the longitudinal direction.

As illustrated in FIG. 24, the first nozzle 141 may be disposed such that the intervals between each first flow path section 61 and other adjacent first flow path sections 61 are different from each other. In such a case, the first nozzle 141 need only be configured with the plurality of first flow path sections 61 disposed such that the intervals between adjacent first flow path sections are different in at least one location. According to the first nozzle 141 having such a configuration, it is possible to adjust the heating effect in the horizontal direction of the first nozzle 141 by adjusting the amount of discharge of the third mixed fluid in the horizontal direction of the first nozzle 141 (the longitudinal direction of the first nozzle 141). Therefore, it is possible to improve the in-plane temperature uniformity of the wafer W.

For example, as illustrated in FIG. 24, in a case where the interval between each first flow path section 61 and other adjacent first flow path sections 61 are set to L1 to L3 in order from the side closest to the center of the wafer W, the plurality of first flow path sections 61 may be disposed so that the relation of L1>L2>L3 is established. With such a configuration, the mount of discharge of the third mixed fluid may be relatively increased at the outer circumference of the wafer W where a drop in temperature is likely to occur, and thus it is possible to effectively improve the in-plane temperature uniformity of the wafer W.

### Other Embodiments

Although examples in which the third mixed fluid (a mixed fluid of an SPM solution and vapor) is discharged from the first nozzle 141 have been described in the sixth to ninth embodiments described above, the first nozzle 141 according to the sixth to ninth embodiments may be configured to discharge the second mixed fluid (a mixed fluid of an SPM solution, vapor, and N₂ gas), similar to the first nozzle 141 according to the first to fifth embodiments.

In addition, in the sixth to ninth embodiments described above, examples in which the third mixed fluid is discharged from all of the ejection ports 441 included in the first nozzle 141 have been described. Without being limited to this, the first nozzle 141 may be configured to discharge the second mixed fluid described in the first to fifth embodiments from some ejection ports 441 among the plurality of ejection ports 441.

As described above, the second mixed fluid into which N₂ gas is mixed has a lower temperature than the third mixed fluid. Consequently, for example, the first nozzle 141 may be configured to discharge the third mixed fluid from the plurality of ejection ports 441 located in the outer circumferential region of the first nozzle 141 corresponding to the outer circumference of the wafer W, and to discharge the second mixed fluid from the plurality of ejection ports 441 located in a central region corresponding to the center of the wafer W. With such a configuration, it is possible to increase the temperature of the mixed fluid discharged from the ejection port 441 at the outer circumference of the wafer W where a drop in temperature is likely to occur. Therefore, it is possible to effectively improve the in-plane temperature uniformity of the wafer W.

Although N₂ gas has been used as an example of an inert gas to be mixed with an SPM solution and vapor in the above-described embodiments, the inert gas may be other inert gases such as helium gas or argon gas.

Although the present disclosure has been described in detail above, the present disclosure is not limited to the above-described embodiments, and various modifications and improvements are possible without departing from the gist of the present disclosure.

The embodiments disclosed herein should be considered to be illustrative and not restrictive in all respects. Indeed, the above-described embodiments may be embodied in various forms. In addition, the above-described embodiments may be omitted, substituted, or modified in various forms without departing from the scope and spirit of the appended claims.

The present technology can also be configured as follows.

(1) A substrate processing apparatus comprising:
a substrate holder configured to rotatably hold a substrate;
a nozzle configured to discharge a mixed fluid onto the substrate, the mixed fluid being a mixture of a fluid containing vapor or mist of pure water, a processing liquid containing at least sulfuric acid, and an inert gas;
a fluid supply configured to supply the fluid to the nozzle;
a processing liquid supply configured to supply the processing liquid to the nozzle;
a gas supply configured to supply the inert gas to the nozzle; and
a gas flow rate adjuster configured to adjust a flow rate of the inert gas supplied from the gas supply to the nozzle.

(2) The substrate processing apparatus according to the above (1), further comprising a controller configured to control the gas flow rate adjuster, wherein the controller executes a temperature adjustment process of adjusting a temperature of the mixed fluid discharged from the nozzle by controlling the gas flow rate adjuster to adjust the flow rate of the inert gas supplied to the nozzle.

(3) The substrate processing apparatus according to the above (2), wherein in the temperature adjustment process, a flow rate of the fluid supplied from the fluid supply and a flow rate of the processing liquid supplied from the processing liquid supply are constant.

(4) The substrate processing apparatus according to the above (2) or (3), further comprising a mover configured to move the nozzle in a horizontal direction,
wherein in the temperature adjustment process, the controller controls the mover to move the nozzle while adjusting the flow rate of the inert gas according to a horizontal position of the nozzle.

(5) The substrate processing apparatus according to the above (4), wherein in the temperature adjustment process, the controller controls the gas flow rate adjuster to adjust the flow rate of the inert gas such that the flow rate of the inert gas when the nozzle is located at an outer circumference of the substrate is smaller than the flow rate of the inert gas when the nozzle is located at a center of the substrate.

(6) The substrate processing apparatus according to any one of the above (1) to (3), wherein the nozzle is an elongated nozzle extending linearly in a horizontal direction, and discharges the mixed fluid from a discharge region extending in the horizontal direction,
the gas supply includes a plurality of individual gas supply paths disposed in the horizontal direction to individually supply the inert gas to the nozzle, and
the gas flow rate adjuster includes a plurality of individual gas flow rate adjusters provided corresponding to the plurality of individual gas supply paths to adjust the flow rate of the inert gas supplied from the individual gas supplies to the nozzle.

(7) The substrate processing apparatus according to the above (6), wherein the nozzle includes
a fluid distribution path connected to the fluid supply and configured to distribute the fluid throughout the entire discharge region,
a processing liquid distribution path connected to the processing liquid supply and configured to distribute the processing liquid throughout the entire discharge region, and
a plurality of individual gas distribution paths provided corresponding to a plurality of individual discharge regions that divide the discharge region in the horizontal direction and configured to distribute the inert gas supplied from the individual gas supply paths to the individual discharge regions.

(8) The substrate processing apparatus according to the above (7), wherein the plurality of individual discharge regions include
a central discharge region corresponding to a central region located at a center of the substrate, and
an outer-circumferential discharge region corresponding to an outer-circumferential region located at an outer circumference of the substrate,
wherein the flow rate of the inert gas supplied to the outer-circumferential discharge region is smaller than the flow rate of the inert gas supplied to the central discharge region.

(9) The substrate processing apparatus according to any one of the above (1) to (8), further comprising:
a first mixer located further upstream than the nozzle and configured to mix the fluid supplied from the fluid supply with the inert gas supplied from the gas supply; and
a second mixer located inside the nozzle and configured to mix the fluid and the inert gas supplied in a mixed state from the first mixer with the processing liquid supplied from the processing liquid supply.

(10) The substrate processing apparatus according to any one of the above (1) to (8), further comprising a fluid mixer located inside the nozzle and configured to mix the fluid supplied from the fluid supply, the processing liquid supplied from the processing liquid supply, and the inert gas supplied from the gas supply.

(11) The substrate processing apparatus according to any one of the above (1) to (10), further comprising:
a second nozzle which is different from a first nozzle which is the nozzle;
a rinse liquid supply configured to supply a rinse liquid to the second nozzle; and
a controller,
wherein the controller is configured to:
discharging the mixed fluid from the first nozzle onto the substrate,
discharging the rinse liquid from the second nozzle to the substrate after the discharging the mixed fluid, and
discharging the inert gas from the first nozzle onto the substrate during the discharging the rinse liquid.

(12) A substrate processing apparatus comprising:
a substrate holder configured to rotatably hold a substrate; and
a nozzle having a shape extending linearly in a horizontal direction and configured to discharge a mixed fluid of a fluid containing vapor or mist of pure water and a processing liquid containing at least sulfuric acid from a discharge region extending in the horizontal direction,
wherein the nozzle includes:
   a plurality of mixers disposed in the horizontal direction, communicating with the discharge region, and configured to mix the fluid with the processing liquid,
   a plurality of first flow path sections disposed in the horizontal direction, communicating with the corresponding mixer, and through which the processing liquid flows, and
   a plurality of second flow path sections disposed in the horizontal direction, communicating with the corresponding mixer, and through which the fluid flows, and
   at least one of the plurality of first flow path sections is different from the other first flow path sections in at least one of the shape and number of flow paths and an interval between the adjacent first flow path sections.

(13) The substrate processing apparatus according to the above (12), wherein a diameter of the flow path in any one of the plurality of first flow path sections is larger than a diameter of the flow path in the first flow path section located closer to a center of the substrate than the one first flow path section.

(14) The substrate processing apparatus according to the above (12) or (13), wherein the mixer includes an ejection port that opens to the discharge region,
at least one of the plurality of first flow path sections includes a plurality of the flow paths, and
the plurality of flow paths are disposed at positions shifted from an axis passing through a center of the ejection port.

(15) The substrate processing apparatus according to any one of the above (12) to (14), wherein the plurality of first flow path sections are detachable from the mixer.

(16) A substrate processing method comprising:
rotatably holding a substrate;
supplying a fluid containing vapor or mist of pure water to a nozzle;
supplying a processing liquid containing at least sulfuric acid to the nozzle;
supplying an inert gas to the nozzle;
discharging a mixed fluid which is a mixture of the fluid, the processing liquid, and the inert gas from the nozzle onto the substrate; and
adjusting a flow rate of the inert gas supplied to the nozzle in the discharging the mixed fluid.

According to the present disclosure, it is possible to achieve the optimization of substrate processing using a mixed fluid obtained by mixing a processing liquid containing at least sulfuric acid with a fluid containing vapor or mist of pure water.

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting, with the true scope and spirit being indicated by the following claims.

What is claimed is:

1. A substrate processing apparatus comprising:
a substrate holder configured to rotatably hold a substrate;
a nozzle configured to discharge a mixed fluid onto the substrate, the mixed fluid being a mixture of a fluid containing vapor or mist of pure water, a processing liquid containing at least sulfuric acid, and an inert gas;
a fluid supply configured to supply the fluid to the nozzle;
a processing liquid supply configured to supply the processing liquid to the nozzle;
a gas supply configured to supply the inert gas to the nozzle; and
a gas flow rate adjuster configured to adjust a flow rate of the inert gas supplied from the gas supply to the nozzle.

2. The substrate processing apparatus according to claim 1, further comprising:
a controller configured to control the gas flow rate adjuster,
wherein the controller executes a temperature adjustment process of adjusting a temperature of the mixed fluid discharged from the nozzle by controlling the gas flow rate adjuster to adjust the flow rate of the inert gas supplied to the nozzle.

3. The substrate processing apparatus according to claim 2, wherein in the temperature adjustment process, a flow rate of the fluid supplied from the fluid supply and a flow rate of the processing liquid supplied from the processing liquid supply are constant.

4. The substrate processing apparatus according to claim 2, further comprising:
a mover configured to move the nozzle in a horizontal direction,
wherein in the temperature adjustment process, the controller controls the mover to move the nozzle while adjusting the flow rate of the inert gas according to a horizontal position of the nozzle.

5. The substrate processing apparatus according to claim 4, wherein in the temperature adjustment process, the controller controls the gas flow rate adjuster to adjust the flow rate of the inert gas such that the flow rate of the inert gas when the nozzle is located at an outer circumference of the substrate is smaller than the flow rate of the inert gas when the nozzle is located at a center of the substrate.

6. The substrate processing apparatus according to claim 1, wherein the nozzle is an elongated nozzle extending linearly in a horizontal direction, and discharges the mixed fluid from a discharge region extending in the horizontal direction,
the gas supply includes a plurality of individual gas supply paths disposed in the horizontal direction to individually supply the inert gas to the nozzle, and
the gas flow rate adjuster includes a plurality of individual gas flow rate adjusters provided corresponding to the plurality of individual gas supply paths to adjust the flow rate of the inert gas supplied from the individual gas supplies to the nozzle.

7. The substrate processing apparatus according to claim 6, wherein the nozzle includes
a fluid distribution path connected to the fluid supply and configured to distribute the fluid throughout the entire discharge region,
a processing liquid distribution path connected to the processing liquid supply and configured to distribute the processing liquid throughout the entire discharge region, and
a plurality of individual gas distribution paths provided corresponding to a plurality of individual discharge regions that divide the discharge region in the horizontal direction and configured to distribute the inert gas supplied from the individual gas supply paths to the individual discharge regions.

8. The substrate processing apparatus according claim 7, wherein the plurality of individual discharge regions include
a central discharge region corresponding to a central region located at a center of the substrate, and
an outer-circumferential discharge region corresponding to an outer-circumferential region located at an outer circumference of the substrate,
wherein the flow rate of the inert gas supplied to the outer-circumferential discharge region is smaller than the flow rate of the inert gas supplied to the central discharge region.

9. The substrate processing apparatus according to claim 1, further comprising:
a first mixer located further upstream than the nozzle and configured to mix the fluid supplied from the fluid supply with the inert gas supplied from the gas supply; and
a second mixer located inside the nozzle and configured to mix the fluid and the inert gas supplied in a mixed state from the first mixer with the processing liquid supplied from the processing liquid supply.

10. The substrate processing apparatus according to claim 1, further comprising a fluid mixer located inside the nozzle and configured to mix the fluid supplied from the fluid supply, the processing liquid supplied from the processing liquid supply, and the inert gas supplied from the gas supply.

11. The substrate processing apparatus according to claim 1, further comprising:
a second nozzle that is different from a first nozzle serving as the nozzle;
a rinse liquid supply configured to supply a rinse liquid to the second nozzle; and
a controller,
wherein the controller is configured to:
discharge the mixed fluid from the first nozzle onto the substrate,
discharge the rinse liquid from the second nozzle to the substrate after the discharging the mixed fluid, and
discharge the inert gas from the first nozzle onto the substrate during the discharging the rinse liquid.

12. A substrate processing apparatus comprising:
a substrate holder configured to rotatably hold a substrate; and
a nozzle having a shape extending linearly in a horizontal direction and configured to discharge a mixed fluid of a fluid containing vapor or mist of pure water and a processing liquid containing at least sulfuric acid from a discharge region extending in the horizontal direction,
wherein the nozzle includes:
a plurality of mixers disposed in the horizontal direction, communicating with the discharge region, and configured to mix the fluid with the processing liquid,
a plurality of first flow path sections disposed in the horizontal direction, communicating with the corresponding mixer, and through which the processing liquid flows, and
a plurality of second flow path sections disposed in the horizontal direction, communicating with the corresponding mixer, and through which the fluid flows, and
at least one of the plurality of first flow path sections is different from the other first flow path sections in at least one of the shape and number of flow paths and an interval between the adjacent first flow path sections.

13. The substrate processing apparatus according to claim 12, wherein a diameter of the flow path in any one of the plurality of first flow path sections is larger than a diameter of the flow path in the first flow path section located closer to a center of the substrate than the one first flow path section.

14. The substrate processing apparatus according to claim 12, wherein the mixer includes an ejection port that opens to the discharge region,
at least one of the plurality of first flow path sections includes a plurality of the flow paths, and
the plurality of flow paths are disposed at positions shifted from an axis passing through a center of the ejection port.

15. The substrate processing apparatus according to claim 12, wherein the plurality of first flow path sections are detachable from the mixer.

16. A substrate processing method comprising:
rotatably holding a substrate;
supplying a fluid containing vapor or mist of pure water to a nozzle;
supplying a processing liquid containing at least sulfuric acid to the nozzle;
supplying an inert gas to the nozzle;
discharging a mixed fluid onto the substrate, the mixed fluid being a mixture of the fluid, the processing liquid, and the inert gas from the nozzle; and
adjusting a flow rate of the inert gas supplied to the nozzle in the discharging the mixed fluid.
